(19) United States
(12) Patent Application Publication
(10) Pub. No.: US 2021/0193861 A1
(43) Pub. Date: Jun. 24, 2021

(54) LASER-ANNEALED PEROVSKITE FILM AND METHOD FOR PREPARING THE SAME

(71) Applicant: THE HONG KONG POLYTECHNIC UNIVERSITY, Hong Kong (CN)

(72) Inventors: Feng YAN, Hong Kong (CN); Peng YOU, Hong Kong (CN)

(21) Appl. No.: 17/247,082

(22) Filed: Nov. 30, 2020

Related U.S. Application Data
(60) Provisional application No. 62/949,475, filed on Dec. 18, 2019.

(51) Int. Cl. H01L 31/18

(52) U.S. Cl. CPC H01L 31/1804; H01L 31/1864

(57) ABSTRACT

The present disclosure provides a laser-annealing method for fabricating large-grain perovskite films for perovskite solar cells based on optimal conditions including laser wavelength, scanning speed and laser power. Compared with the conventional technology, the present laser-annealing method provides the laser-annealed perovskite films with better crystallinity and larger grains thereby improving the photovoltaic performance of the perovskite solar cells.

### CROSS-REFERENCE TO RELATED APPLICATIONS

This application claims the benefit of U.S. Provisional Patent Application No. 62/949,475, filed on Dec. 18, 2019, which is incorporated by reference herein in its entirety.

### PRIOR DISCLOSURE BY THE INVENTOR OR A JOINT INVENTOR

Part of the present invention was disclosed in a paper published in the Energy & Environmental Science (DOI: 10.1039/c9ee02324k) on 29 Nov. 2019. The paper is a grace period inventor-originated disclosure disclosed within one year before the effective filing date of this application.

### TECHNICAL FIELD

The present disclosure generally relates to a laser-annealed perovskite film and a method for preparing the same.

### BACKGROUND

Organic-inorganic hybrid perovskite solar cells (PSCs) have attracted tremendous attention in recent years due to their high power conversion efficiency (PCE) and low fabrication cost. The unique properties of the organic-inorganic hybrid perovskites, like the high light absorption coefficient, high carrier mobilities, small exciton binding energy and long carrier diffusion lengths, are responsible for the high photovoltaic performance of PSCs. Since the first report of PSCs with a PCE of 3.8% in 2009, the certified efficiency was improved rapidly to over 25% in the past decade.

The crystallinity of perovskite films has been found to be critical to the device performance. Perovskite films with larger grains normally have lower density of trap states and higher carrier mobilities, which can lead to reduced carrier recombination and enhanced photovoltaic performance of perovskite solar cells (PSCs).

The annealing conditions of perovskite films are detrimental to the growth of perovskite grains. However, it is challenging to precisely control the crystallization of perovskite films based on a conventional thermal annealing method. Besides, a thermal-annealing process is time-consuming and incompatible with low-temperature fabrication required by certain devices such as flexible PSCs on plastic substrates. Therefore, novel annealing approaches are desirable to overcome these limitations.

Laser-annealing techniques have been successfully used in semiconductor industry for the mass production of large-scale devices. They can be utilized for the treatment of various materials, like silicon, metal oxides and nanomaterials, and demonstrate numerous advantages over thermal annealing, including controllable crystallization, low-temperature processing, large-area fabrication and being a non-contact process. More importantly, a uniform annealing process can be achieved on large-area samples of arbitrary shapes by scanning the laser spot on their surfaces, which can hardly be realized with other heating methods. Complex patterns can be produced by scanning the laser spot in a programmable path with computer-aided designs. Furthermore, a suitable temperature gradient induced by localized laser-annealing can be favorable for crystal growth. Although some attempts of using laser to anneal perovskite films have been reported, no high-performance PSCs have been realized based on the technology until now. Besides, photonic flash annealing of perovskite films has been demonstrated by using white light or infrared light. However, these methods will induce high substrate temperatures, and the device efficiencies are even lower than those of the control devices.

A need therefore exists for an improved method for preparing a laser-annealed perovskite film that eliminates or at least diminishes the disadvantages and problems described above.

### SUMMARY OF THE INVENTION

Provided herein is a method for preparing a laser-annealed perovskite film by one or more laser beams comprising: providing an as-deposited perovskite film having an amorphous phase and comprising a plurality of perovskite crystallites, each perovskite crystallite being surrounded by the amorphous phase; determining a light wavelength, at which a light absorbance ratio of the plurality of perovskite crystallites to the amorphous phase in a spectral region is larger than a threshold value, the threshold value being 80% of a largest value of the light absorbance ratio in the spectral region; selecting a wavelength of each laser beam to be the determined light wavelength such that the plurality of perovskite crystallites absorbs more energy from the one or more laser beams and attains higher temperature than the amorphous phase thereby inducing selective growth of the plurality of perovskite crystallites for improving crystallinity of the laser-annealed perovskite film and increasing an average grain size of the laser-annealed perovskite film; selecting a power and a scanning speed of each laser beam such that when an area of the as-deposited perovskite film is scanned by an individual laser beam with the selected wavelength, a surface temperature of the area is raised to a crystallization temperature of the as-deposited perovskite film for improving the crystallinity and increasing the average grain size; and scanning one or more surfaces of the perovskite film by the one or more laser beams with the selected wavelength, the selected power and the selected scanning speed for annealing the as-deposited perovskite film to crystallize the as-deposited perovskite film under the selective growth of the plurality of perovskite crystallites thereby forming the laser-annealed perovskite film such that when the laser-annealed perovskite film is used in a perovskite solar cell, photovoltaic performance of the perovskite solar cell is enhanced.

In certain embodiments, wherein the step of determining the light wavelength comprises: characterizing a sample of the as-deposited perovskite film with absorption spectroscopy for obtaining a first absorption spectrum; crystallizing the sample of the as-deposited perovskite film thereby forming a crystalline perovskite film; characterizing the crystalline perovskite film with absorption spectroscopy for obtaining a second absorption spectrum; determining a light absorbance ratio of the crystalline perovskite film to the sample of the as-deposited perovskite film in the spectral region based on the first absorbance spectrum and the second absorbance spectrum; and selecting the light wavelength, at which the determined light absorbance ratio of the crystalline perovskite film to the sample the as-deposited perovskite film in the spectral region is larger than the threshold value.

In certain embodiments, the crystalline perovskite film is formed by laser-annealing or thermal annealing.

In certain embodiments, the threshold value is 90% of the largest value.

In certain embodiments, the spectral region is between 300 nm and 800 nm.

In certain embodiments, each laser beam is a linear laser beam or a spot laser beam; and the selected scanning speed is controlled by a motorized stage.

In certain embodiments, the as-deposited perovskite film is prepared by a spin-coating method.

In certain embodiments, the as-deposited perovskite film consists of methylammonium lead iodide (MAPbI₃) or a mixed perovskite material having a chemical formula of (CsPbI₃)_{0.05}(FAPbI₃)_{0.95}(MAPbBr₃)_{0.05}.

Provided herein is a method for preparing a laser-annealed perovskite film by one or more laser beams comprising: providing an as-deposited perovskite film having an amorphous phase and comprising a plurality of perovskite crystallites, each perovskite crystallite being surrounded by the amorphous phase; and scanning one or more surfaces of the as-deposited perovskite film by the one or more laser beams with a predetermined wavelength, a predetermined power and a predetermined scanning speed for annealing the as-deposited perovskite film to crystallize the as-deposited perovskite film thereby forming the laser-annealed perovskite film; wherein the predetermined wavelength is selected to be a light wavelength at which a light absorbance ratio of the plurality of perovskite crystallites to the amorphous phase in a spectral region is larger than a threshold value, the threshold value being 80% of a largest value of the light absorbance ratio in the spectral region such that the plurality of perovskite crystallites absorbs more energy from the one or more laser beams and attains higher temperature than the amorphous phase thereby inducing selective growth of the plurality of perovskite crystallites for improving crystallinity of the laser-annealed perovskite film and increasing an average grain size of the laser-annealed perovskite film; wherein the predetermined power and the predetermined scanning speed are selected such that when an area of the as-deposited perovskite film is scanned by an individual laser beam with the predetermined wavelength, a surface temperature of the area is raised to a crystallization temperature of the as-deposited perovskite film for improving the crystallinity and increasing the average grain size; and wherein the laser-annealed perovskite film is formed under the selective growth of the plurality of perovskite crystallites such that when the laser-annealed perovskite film is used in a perovskite solar cell, photovoltaic performance of the perovskite solar cell is enhanced.

In certain embodiments, each laser beam is a linear laser beam or a spot laser beam.

In certain embodiments, the spot laser beam has a spot size between 0.5 mm and 1.0 mm.

In certain embodiments, the linear laser beam is generated by a cylindrical convex lens and a laser generator.

In certain embodiments, each laser beam is generated by a laser generator.

In certain embodiments, the laser generator is mounted on a motorized stage for controlling the predetermined scanning speed.

Provided herein is a method for preparing a laser-annealed perovskite film by one or more laser beams comprising: providing an as-deposited perovskite film having an amorphous phase and comprising a plurality of perovskite crystallites, each perovskite crystallite being surrounded by the amorphous phase; and scanning one or more surfaces of the as-deposited perovskite film by the one or more laser beams with a predetermined wavelength, a predetermined power and a predetermined scanning speed for annealing the as-deposited perovskite film to crystallize the as-deposited perovskite film thereby forming the laser-annealed perovskite film; wherein the as-deposited perovskite film consists of MAPbI₃ or a mixed perovskite material having a chemical formula of (CsPbI₃)_{0.05}(FAPbI₃)_{0.95}(MAPbBr₃)_{0.05}; wherein the predetermined wavelength is between 445 nm and 455 nm such that the plurality of perovskite crystallites absorbs more energy from the one or more laser beams and attains higher temperature than the amorphous phase thereby inducing selective growth of the plurality of perovskite crystallites for improving crystallinity of the laser-annealed perovskite film and increasing an average grain size of the laser-annealed perovskite film; wherein the predetermined power is between 145 mW and 155 mW and the predetermined scanning speed is between 20 mm/min and 30 mm/min such that when an area of the perovskite film is scanned by an individual laser beam with the predetermined wavelength, a surface temperature of the area is raised to a crystallization temperature of the as-deposited perovskite film for improving the crystallinity and increasing the average grain size; and wherein the laser-annealed perovskite film is formed under the selective growth of the plurality of perovskite crystallites such that when the laser-annealed perovskite film is used in a perovskite solar cell, photovoltaic performance of the perovskite solar cell is enhanced.

Provided herein is a laser-annealed perovskite film prepared by the method described above.

Provided herein is a perovskite solar cell comprising a laser-annealed perovskite film prepared by the method described above.

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Other aspects of the present invention are disclosed as illustrated by the embodiments hereinafter.

### BRIEF DESCRIPTION OF DRAWINGS

The appended drawings, where like reference numerals refer to identical or functionally similar elements, contain figures of certain embodiments to further illustrate and clarify the above and other aspects, advantages and features of the present invention. It will be appreciated that these drawings depict embodiments of the invention and are not intended to limit its scope. The invention will be described and explained with additional specificity and detail through the use of the accompanying drawings in which:

FIG. 1 is a flow chart depicting a method for preparing a laser-annealed perovskite film according to certain embodiments;

FIG. 2 is a flow chart depicting a method for preparing a laser-annealed perovskite film according to certain embodiments;

FIG. 3A shows schematic illustration of a laser annealing process according to certain embodiments, in which insets show photos of the as-deposited (left) and laser-annealed (right) perovskite films;

FIG. 3B shows a 2D infrared thermal image of the MAPbI₃ perovskite film surface during the laser annealing process (450-nm laser, 150 mW, 25 mm/min) by an infrared thermal imager;

FIG. 3C shows a 3D infrared thermal image of the MAPbI₃ perovskite film surface during the laser annealing process (450-nm laser, 150 mW, 25 mm/min);

FIG. 3D shows temperature distribution on the MAPbI₃ perovskite film surface along the dash line in FIG. 3B;

FIG. 3E shows XRD spectra of FTO/TiO₂ and FTO/TiO₂/MAPbI₃ films;

FIG. 3F shows MAPbI₃ perovskite film patterned with focused laser beam, in which an inset shows the black-white picture used as template for laser patterning process;

FIG. 4A shows a laser-annealing system controlled by a computer according to certain embodiments;

FIG. 4B shows an illustration of the laser scanning track with a fixed step distance according to certain embodiment;

FIG. 5 shows XRD spectrum of the as-deposited MAPbI₃ perovskite film, showing (110), (220) and (310) diffraction peaks of tetragonal MAPbI₃ perovskite phase;

FIG. 6A shows the infrared thermal image of a MAPbI₃ perovskite film on a hotplate with a surface temperature of around 100° C.;

FIG. 6B shows the temperature distribution on the sample surface (along the line in FIG. 6A);

FIG. 7A shows Infrared thermal images of MAPbI₃ perovskite films during a laser-annealing process with 450-nm laser, and the laser output power was set as 150 mW for the laser;

FIG. 7B shows Infrared thermal images of MAPbI₃ perovskite films during a laser-annealing process with 405-nm laser, and the laser output power was set as 150 mW for the laser;

FIG. 7C shows Infrared thermal images of MAPbI₃ perovskite films during a laser-annealing process with 660-nm laser, and the laser output power was set as 150 mW for the laser;

FIG. 8 shows XRD pattern of the decomposed MAPbI₃ perovskite film after laser-patterning process by focused laser beam;

FIG. 9A shows a plan-view SEM image of a MAPbI₃ perovskite film fabricated by a thermal-annealing process, in which an inset shows the statistical diagrams of the grain size distribution based on the SEM image;

FIG. 9B shows a plan-view SEM image of a MAPbI₃ perovskite film fabricated by a laser-annealing process with 405-nm laser, in which an inset shows the statistical diagrams of the grain size distribution based on the SEM image;

FIG. 9C shows a plan-view SEM image of a MAPbI₃ perovskite film fabricated by a laser-annealing process with 450-nm lasers, in which an inset shows the statistical diagrams of the grain size distribution based on the SEM image;

FIG. 9D shows a plan-view SEM image of a MAPbI₃ perovskite film fabricated by a laser-annealing process with 660-nm laser, in which an inset shows the statistical diagrams of the grain size distribution based on the SEM image;

FIG. 9E shows UV-vis absorbance spectra of the as-deposited and laser-annealed MAPbI₃ perovskite films, along with the absorbance ratio between the two films;

FIG. 9F shows a schematic diagram of the perovskite crystallization process under the illumination of laser beams, in which arrows show growth directions of perovskite crystallites;

FIG. 10A shows a cross-sectional SEM image of a thermal-annealed MAPbI₃ perovskite film on a FTO/TiO₂ substrate;

FIG. 10B shows a cross-sectional SEM image of a laser-annealed MAPbI₃ perovskite film on a FTO/TiO₂ substrate;

FIG. 11 shows the time dependent temperature of the MAPbI₃ perovskite surface under a laser spot with a scanning speed of 25 mm/min, the annealing time above 80° C. is 1.5 s, the surface temperature is increased by laser with the maximum rate of 43° C./s (slope of the dash line);

FIG. 12A shows a SEM image of a MAPbI₃ perovskite film fabricated at a laser scanning speed of 10 mm/min, 450-nm laser was used, and the laser output power was fixed at 150 mW;

FIG. 12B shows a SEM image of a MAPbI₃ perovskite film fabricated at a laser scanning speed of 25 mm/min, 450-nm laser was used, and the laser output power was fixed at 150 mW;

FIG. 12C shows a SEM image of a MAPbI₃ perovskite film fabricated at a laser scanning speed of 50 mm/min, 450-nm laser was used, and the laser output power was fixed at 150 mW;

FIG. 12D shows a SEM image of a MAPbI₃ perovskite film fabricated at a laser scanning speed of 100 mm/min, 450-nm laser was used, and the laser output power was fixed at 150 mW;

FIG. 13A shows an infrared thermal image of a MAPbI₃ perovskite film during a laser-annealing process with a laser scanning speed of 100 mm/min;

FIG. 13B shows an infrared thermal image of a MAPbI₃ perovskite film during a laser-annealing process with a laser scanning speed of 50 mm/min;

FIG. 13C shows an infrared thermal image of a MAPbI₃ perovskite film during a laser-annealing process with a laser scanning speed of 25 mm/min;

FIG. 13D shows an infrared thermal image of a MAPbI₃ perovskite film during a laser-annealing process with a laser scanning speed of 10 mm/min;

FIG. 13E shows the central surface temperatures of the perovskite films derived from the infrared thermal images at different laser scanning speeds;

FIG. 14A shows a SEM image of a MAPbI₃ perovskite film fabricated at a laser output power of 110 mW, 450-nm laser was used, and the laser scanning speed was fixed at 25 mm/min;

FIG. 14B shows a SEM image of a MAPbI₃ perovskite film fabricated at a laser output power of 130 mW, 450-nm laser was used, and the laser scanning speed was fixed at 25 mm/min;

FIG. 14C shows a SEM image of a MAPbI₃ perovskite film fabricated at a laser output power of 150 mW, 450-nm laser was used, and the laser scanning speed was fixed at 25 mm/min;

FIG. 14D shows a SEM image of a MAPbI₃ perovskite film fabricated at a laser output power of 170 mW, 450-nm laser was used, and the laser scanning speed was fixed at 25 mm/min;

FIG. 15A shows an infrared thermal image of a MAPbI₃ perovskite films during a laser-annealing process with a laser output power of 110 mW;

FIG. 15B shows an infrared thermal image of a MAPbI₃ perovskite film during a laser-annealing process with a laser output power of 130 mW;

FIG. 15C shows an infrared thermal image of a MAPbI₃ perovskite film during a laser-annealing process with a laser output power of 150 mW;

FIG. 15D shows an infrared thermal image of a MAPbI₃ perovskite film during a laser-annealing process with a laser output power of 170 mW;

FIG. 15E shows the central surface temperatures of the perovskite films derived from the infrared thermal images at different laser output power;

FIG. 16A shows a schematic diagram of the solar cell structure according to certain embodiments;

FIG. 16B shows J-V curves of the best MAPbI₃ PSCs fabricated by thermal-annealing and laser-annealing processes;

FIG. 16C shows EQE spectra of the best MAPbI₃ PSCs fabricated by thermal-annealing and laser-annealing processes;

FIG. 16D shows histogram of PCEs derived from the reverse scans of 40 devices fabricated at the optimum conditions;

FIG. 17 shows steady-state photocurrent and efficiency of the best MAPbI₃ PSC measured at a bias voltage (0.96 V) at the maximum power point;

FIG. 18A shows J-V characteristics of the MAPbI₃ PSCs fabricated at different laser scanning speeds, 450-nm laser was used, and the laser output power was 150 mW;

FIG. 18B shows J-V characteristics of the MAPbI₃ PSCs fabricated at different laser output power, 450-nm laser was used, and the laser scan speed was 25 mm/min;

FIG. 18C shows the relationship between the device efficiency and laser scanning speeds;

FIG. 18D shows the relationship between the device efficiency and laser output power;

FIG. 19A shows steady-state photoluminescence (PL) spectra of MAPbI₃ perovskite films prepared by thermal-annealing and laser-annealing approaches;

FIG. 19B shows time-resolved PL spectra of MAPbI₃ perovskite films prepared by thermal-annealing and laser-annealing approaches;

FIG. 19C shows electrochemical impedance spectra of MAPbI₃ PSCs measured at a bias voltage of 0.80 V under light illumination of 100 mW/cm² (white light);

FIG. 19D shows the recombination resistance of the MAPbI₃ PSCs derived from impedance spectra biased at different voltages under light illumination of 100 mW/cm²;

FIG. 20A shows the impedance spectra of MAPbI₃ PSCs after thermal-annealing at different bias voltages under light illumination of 100 mW/cm²;

FIG. 20B shows the impedance spectra of MAPbI₃ PSCs after laser-annealing at different bias voltages under light illumination of 100 mW/cm²;

FIG. 21A shows the evolution of PCE of MAPbI₃ PSCs during stability tests (average of 10 devices for each condition), all the devices were encapsulated and kept in air with relative humidity of around 30% (in dark);

FIG. 21B shows the evolution of Voc of MAPbI₃ PSCs during stability tests (average of 10 devices for each condition), all the devices were encapsulated and kept in air with relative humidity of around 30% (in dark);

FIG. 21C shows the evolution of Jsc of MAPbI₃ PSCs during stability tests (average of 10 devices for each condition), all the devices were encapsulated and kept in air with relative humidity of around 30% (in dark);

FIG. 21D shows the evolution of FF of MAPbI₃ PSCs during stability tests (average of 10 devices for each condition), all the devices were encapsulated and kept in air with relative humidity of around 30% (in dark);

FIG. 22A shows a schematic diagram of the laser-annealing process with a linear laser beam according to certain embodiments;

FIG. 22B shows an infrared thermal image of the MAPbI₃ perovskite film surface during laser scanning process by using a linear laser beam;

FIG. 22C shows J-V curve of the best MAPbI₃ PSC fabricated with the linear laser beam (device area ˜6 mm²);

FIG. 22D shows J-V characteristics of the large-area MAPbI₃ PSCs prepared with the linear laser beam (area ˜1.0 cm²);

FIG. 23A shows the infrared thermal image of the scanning linear laser beam on the as-deposited MAPbI₃ perovskite film, and the laser beam was moving along the y axis direction;

FIG. 23B shows the temperature distribution of the linear laser beam along x direction;

FIG. 23C shows the temperature distribution of the linear laser beam along y direction;

FIG. 24A shows infrared thermal images of (CsPbI₃)_{0.05}(FAPbI₃)_{0.95}(MAPbBr₃)_{0.05} mixed perovskite films during a laser-annealing process with 450-nm laser, and the laser scanning speed was 25 mm/min;

FIG. 24B shows infrared thermal images of (CsPbI₃)_{0.05}(FAPbI₃)_{0.95}(MAPbBr₃)_{0.05} mixed perovskite films during a laser-annealing process 405-nm laser, the laser scanning speed was 25 mm/min;

FIG. 24C shows infrared thermal images of (CsPbI₃)_{0.05}(FAPbI₃)_{0.95}(MAPbBr₃)_{0.05} mixed perovskite films during a laser-annealing process 660-nm laser, the laser scanning speed was 25 mm/min;

FIG. 25 shows the time-dependent temperature of the mixed perovskite surface under a 450-nm laser spot with a scanning speed of 25 mm/min, and the surface temperature is increased by laser with the maximum rate of 100° C./s (slope of the dash line);

FIG. 26A shows a SEM image of a mixed perovskite film fabricated by a thermal-annealing process, in which an inset shows the statistical diagrams of the grain size distribution based on the SEM image;

FIG. 26B shows a SEM image of a mixed perovskite film fabricated by a laser-annealing process with 405-nm laser, in which an inset shows the statistical diagrams of the grain size distribution based on the SEM image;

FIG. 26C shows a SEM image of a mixed perovskite film fabricated by a laser-annealing process with 450-nm laser, in which an inset shows the statistical diagrams of the grain size distribution based on the SEM image;

FIG. 26D shows a SEM image of a mixed perovskite film fabricated by a laser-annealing process with 660-nm laser, in which an inset shows the statistical diagrams of the grain size distribution based on the SEM image;

FIG. 26E shows J-V curves of the best devices fabricated by thermal-annealing and laser-annealing processes;

FIG. 26F shows steady-state photocurrent and efficiency of the champion device measured at the maximum power point;

FIG. 27 shows UV-vis absorbance spectra of the as-deposited and laser-annealed mixed perovskite films, along with the absorbance ratio between the two films;

FIG. 28A shows J-V characteristics of the best mixed PSCs fabricated by thermal-annealing and laser-annealing processes;

FIG. 28B shows EQE spectra of the best mixed PSCs fabricated by thermal-annealing and laser-annealing processes;

FIG. 29A shows EQE spectra of the best MAPbI₃;

FIG. 29B shows EQE spectra of the best mixed PSCs;

FIG. 29C shows a semi-log plot of EQE values versus photon energy for the best MAPbI₃;

FIG. 29D shows a semi-log plot of EQE values versus photon energy for the best mixed PSCs;

FIG. 30A shows stability tests of the encapsulated mixed PSCs under dark, all the tests were carried out in ambient air with relative humidity around 30%; and

FIG. 30B shows stability tests of the encapsulated mixed PSCs under light illumination of 100 mW/cm² (AM 1.5G), all the tests were carried out in ambient air with relative humidity around 30%, the device temperature during light soaking was around 40° C.

Skilled artisans will appreciate that elements in the figures are illustrated for simplicity and clarity and have not necessarily been depicted to scale.

### DETAILED DESCRIPTION OF THE INVENTION

As used herein in the specification and appended claims, the term “avoid” or “avoiding” refers to any method to partially or completely preclude, avert, obviate, forestall, stop, hinder or delay the consequence or phenomenon following the term “avoid” or “avoiding” from happening. The term “avoid” or “avoiding” does not mean that it is necessarily absolute, but rather effective for providing some degree of avoidance or prevention or amelioration of consequence or phenomenon following the term “avoid” or “avoiding”.

It will be apparent to those skilled in the art that modifications, including additions and/or substitutions, may be made without departing from the scope and spirit of the invention. Specific details may be omitted so as not to obscure the invention; however, the disclosure is written to enable one skilled in the art to practice the teachings herein without undue experimentation.

The present disclosure provides a laser-annealed perovskite film and a method for preparing a laser-annealed perovskite film by laser beam scanning. The laser-annealing process is optimized by tuning the laser scanning conditions, including laser wavelength, laser power and scanning speed. The laser-annealed perovskite films demonstrate larger grain sizes than thermal-annealed perovskite films, which can be attributed to the temperature gradient generated between perovskite crystallites and the amorphous components around them due to different light absorption coefficients of the two phases. Under the optimum conditions, the average power conversion efficiency (PCE) of the devices is relatively improved for about 20% in comparison with the control devices prepared by thermal annealing according to certain embodiments. By using a linear laser beam, large-area devices can be prepared with a high speed, which paves a way for the mass production of PSCs at a low temperature.

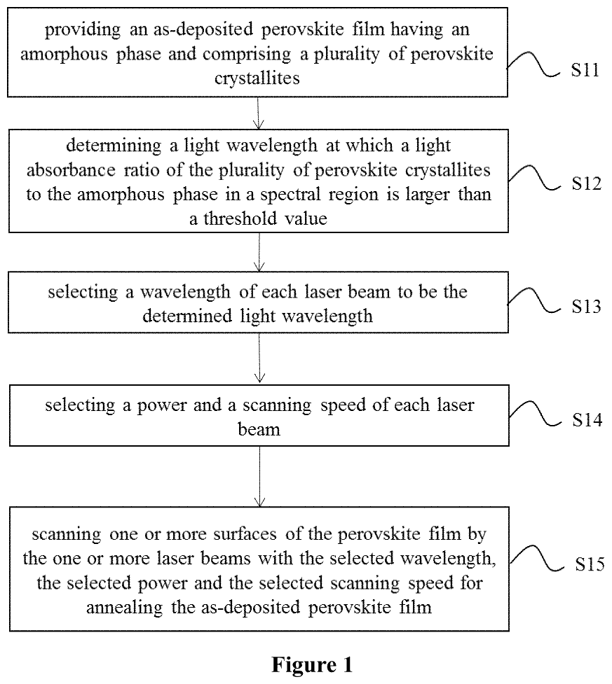

FIG. 1 is a flow chart depicting a method for preparing a laser-annealed perovskite film according to certain embodiments. In step S11, an as-deposited perovskite film having an amorphous phase and comprising a plurality of perovskite crystallites is provided, each perovskite crystallite is surrounded by the amorphous phase. In step S12, a light wavelength is determined, at which a light absorbance ratio of the plurality of perovskite crystallites to the amorphous phase in a spectral region is larger than a threshold value, the threshold value is 80% of a largest value of the light absorbance ratio in the spectral region. In step S13, a wavelength of each laser beam is selected to be the determined light wavelength such that the plurality of perovskite crystallites absorbs more energy from the one or more laser beams and attains higher temperature than the amorphous phase thereby inducing selective growth of the plurality of perovskite crystallites for improving crystallinity of the laser-annealed perovskite film and increasing an average grain size of the laser-annealed perovskite film. In step S14, a power and a scanning speed of each laser beam are selected such that when an area of the perovskite film is scanned by an individual laser beam with the selected wavelength, a surface temperature of the area is raised to a crystallization temperature of the as-deposited perovskite film for improving the crystallinity and increasing the average grain size. In step S15, one or more surfaces of the perovskite film are scanned by the one or more laser beams with the selected wavelength, the selected power and the selected scanning speed for annealing the as-deposited perovskite film to crystallize the as-deposited perovskite film under the selective growth of the plurality of perovskite crystallites thereby forming the laser-annealed perovskite film such that when the laser-annealed perovskite film is used in a perovskite solar cell, photovoltaic performance of the perovskite solar cell is enhanced.

In certain embodiments, the step of determining the light wavelength comprises: characterizing a sample of the as-deposited perovskite film with absorption spectroscopy for obtaining a first absorption spectrum; crystallizing the sample of the as-deposited perovskite film thereby forming a crystalline perovskite film; characterizing the crystalline perovskite film with absorption spectroscopy for obtaining a second absorption spectrum; determining a light absorbance ratio of the crystalline perovskite film to the sample of the as-deposited perovskite film in the spectral region based on the first absorbance spectrum and the second absorbance spectrum; and selecting the light wavelength, at which the determined light absorbance ratio of the crystalline perovskite film to the sample the as-deposited perovskite film in the spectral region is larger than the threshold value.

In certain embodiments, the crystalline perovskite film is formed by laser-annealing or thermal annealing.

In certain embodiments, the threshold value is 95% of the largest value, 90% of the largest value, or 85% of the largest value.

In certain embodiments, the spectral region is between 300 nm and 800 nm, or 350 nm or 700 nm.

In certain embodiments, each laser beam is a linear laser beam or a spot laser beam; and the scanning speed is controlled by a motorized stage.

In certain embodiments, the as-deposited perovskite film consists of methylammonium lead iodide (MAPbI₃) or a mixed perovskite material having a chemical formula of (CsPbI₃)_{0.05}(FAPbI₃)_{0.95}(MAPbBr₃)_{0.05}.

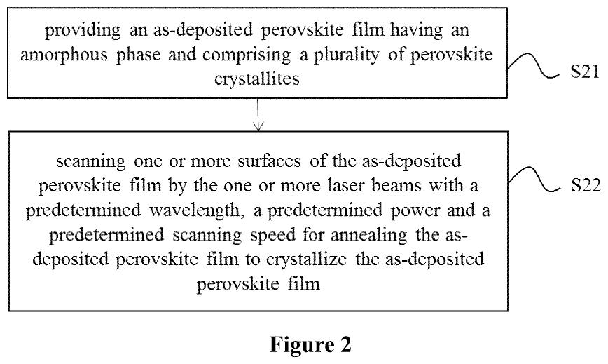

FIG. 2 is a flow chart depicting a method for preparing a laser-annealed perovskite film according to certain embodiments. In step S21, an as-deposited perovskite film having an amorphous phase and comprising a plurality of perovskite crystallites is provided, each perovskite crystallite is surrounded by the amorphous phase. In step S22, one or more surfaces of the as-deposited perovskite film are scanned by the one or more laser beams with a predetermined wavelength, a predetermined power and a predetermined scanning speed for annealing the as-deposited perovskite film to crystallize the as-deposited perovskite film thereby forming the laser-annealed perovskite film.

In certain embodiments, the predetermined wavelength is selected to be a light wavelength at which a light absorbance ratio of the plurality of perovskite crystallites to the amorphous phase in a spectral region is larger than a threshold value, the threshold value being 80% of a largest value of the light absorbance ratio in the spectral region such that the plurality of perovskite crystallites absorbs more energy from the one or more laser beams and attains higher temperature than the amorphous phase thereby inducing selective growth of the plurality of perovskite crystallites for improving crystallinity of the laser-annealed perovskite film and increasing an average grain size of the laser-annealed perovskite film; the predetermined power and the predetermined scanning speed are selected such that when an area of the as-deposited perovskite film is scanned by an individual laser beam with the predetermined wavelength, a surface temperature of the area is raised to a crystallization temperature of the as-deposited perovskite film for improving the crystallinity and increasing the average grain size; and the laser-annealed perovskite film is formed under the selective growth of the plurality of perovskite crystallites such that when the laser-annealed perovskite film is used in a perovskite solar cell, photovoltaic performance of the perovskite solar cell is enhanced.

In certain embodiments, the as-deposited perovskite film consists of MAPbI₃ or a mixed perovskite material having a chemical formula of (CsPbI₃)_{0.05}(FAPbI₃)_{0.95}(MAPbBr₃)_{0.05}; the predetermined wavelength is between 445 nm and 455 nm such that the plurality of perovskite crystallites absorbs more energy from the one or more laser beams and attains higher temperature than the amorphous phase thereby inducing selective growth of the plurality of perovskite crystallites for improving crystallinity of the laser-annealed perovskite film and increasing an average grain size of the laser-annealed perovskite film; the predetermined power is between 145 mW and 155 mW and the predetermined scanning speed is between 20 mm/min and 30 mm/min such that when an area of the as-deposited perovskite film is scanned by an individual laser beam with the predetermined wavelength, a surface temperature of the area is raised to a crystallization temperature of the as-deposited perovskite film for improving the crystallinity and increasing the average grain size; and the laser-annealed perovskite film is formed under the selective growth of the plurality of perovskite crystallites such that when the laser-annealed perovskite film is used in a perovskite solar cell, photovoltaic performance of the perovskite solar cell is enhanced.

In certain embodiments, each laser beam is a linear laser beam or a spot laser beam.

In certain embodiments, the spot laser beam has a spot size between 0.5 mm and 1.0 mm.

In certain embodiments, the linear laser beam is generated by a cylindrical convex lens and a laser generator.

In certain embodiments, each laser beam is generated by a laser generator.

In certain embodiments, the laser generator is mounted on a motorized stage for controlling the predetermined scanning speed.

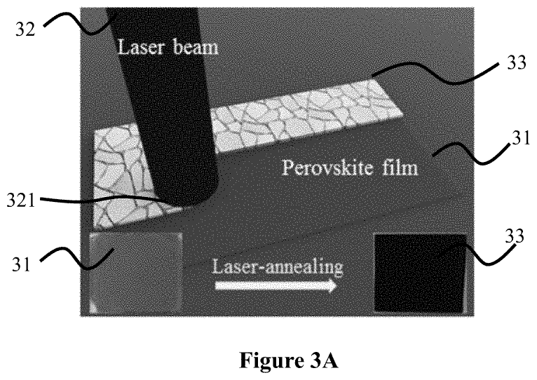

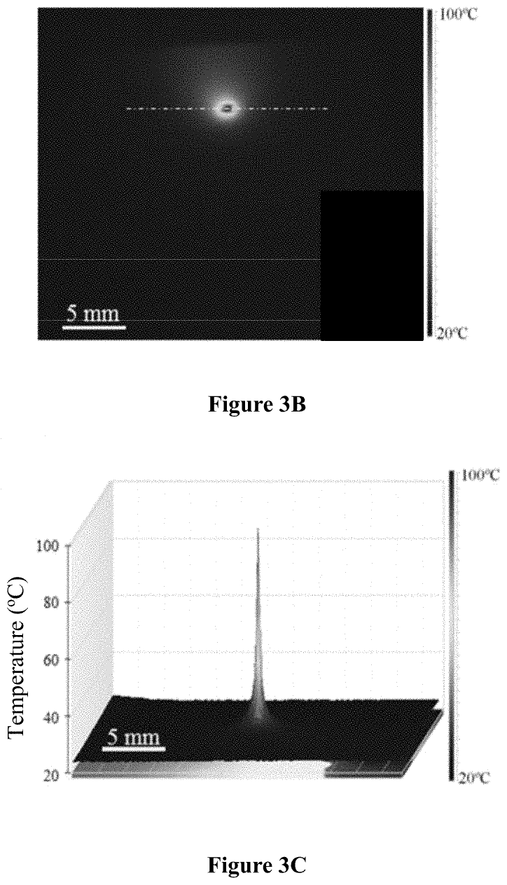

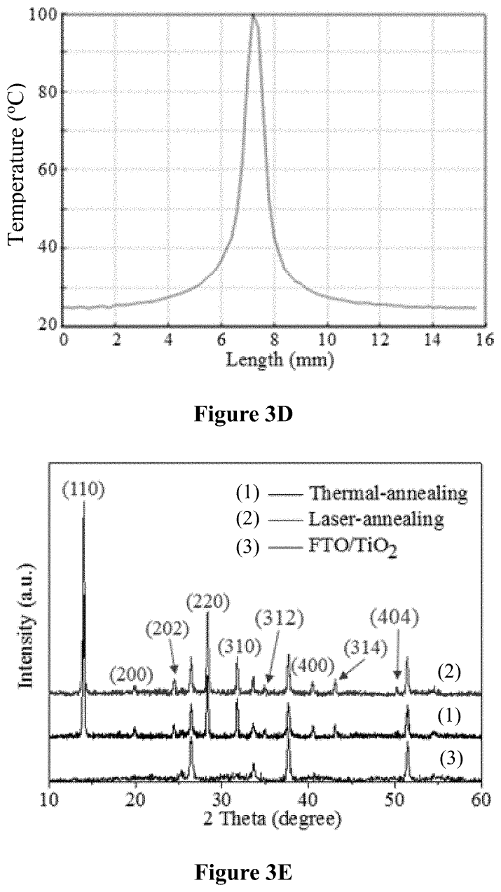

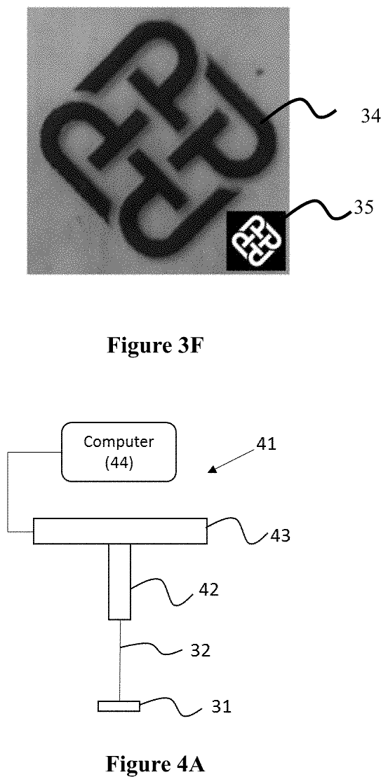

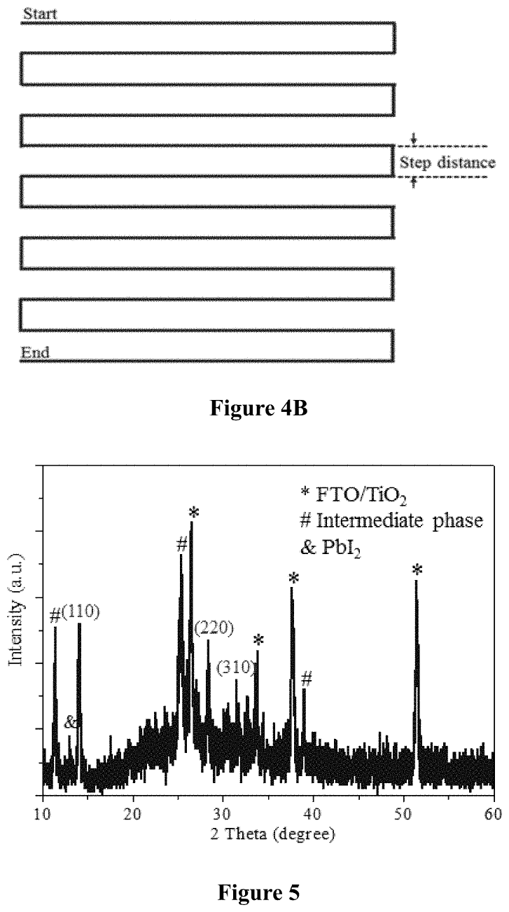

FIG. 3A shows the schematic illustration of the laser annealing process according to certain embodiments. MAPbI₃ perovskite films were prepared by using an antisolvent-assisted spin-coating method. Then, a robotic laser scanning system 41 (See FIG. 4A) was used to anneal the as-deposited perovskite film 31. A continuous-wave laser diode 42 with controllable output power was fixed on an X-Y motorized stage 43. The downward laser beam 32 scanned along a designed track on the sample surface with a speed (See FIG. 4B) under the control of a computer 44. The laser spot on film surface was controlled to have a diameter of 1.0 mm. The laser diode 42 with different wavelengths (405 nm, 450 nm and 660 nm) was used in film annealing. Notably, as-deposited perovskite films 31 were light brown (See the left inset of FIG. 3A), indicating that they were partially crystalized before annealing. The coexistence of crystalline and amorphous phases in as-deposited perovskite films was also confirmed by X-ray diffraction (XRD) patterns (See FIG. 5). After the laser scanning processes, a laser-annealed perovskite film 33 was completely crystallized and turned into black (See the right inset of FIG. 3A).

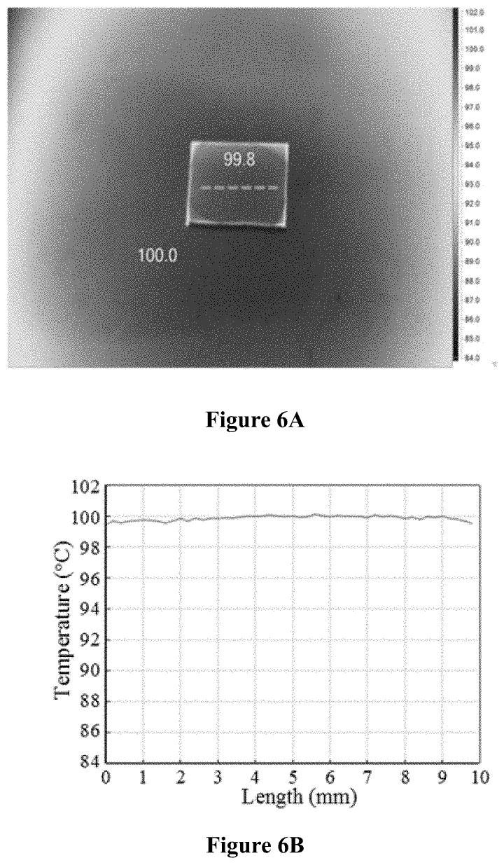

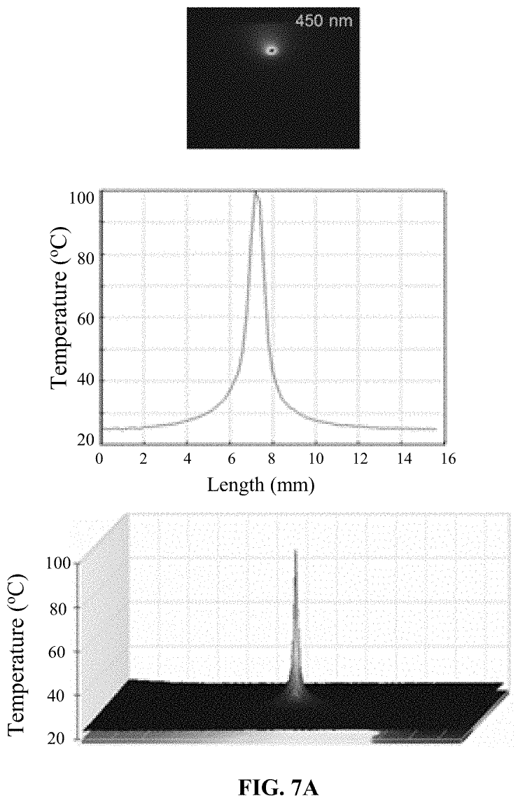

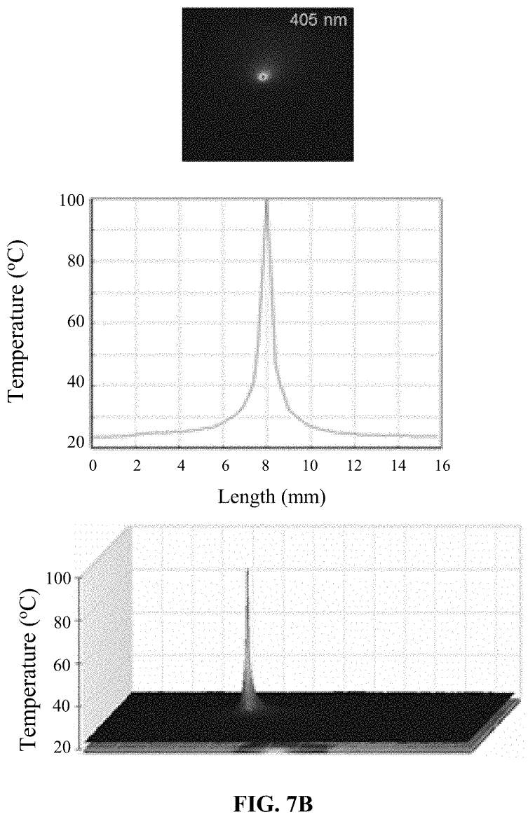

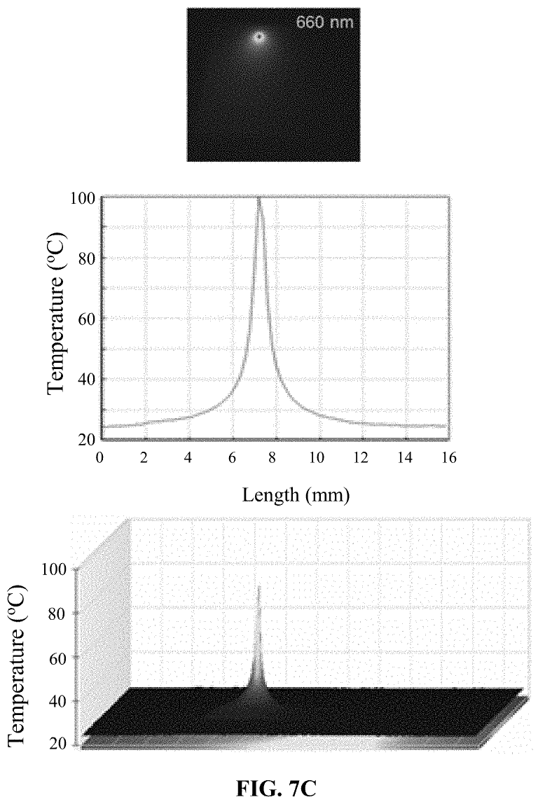

The surface temperature distribution of a perovskite film was monitored by an infrared thermal imager during the laser annealing process (wavelength: 450 nm). FIGS. 3B and 3C show the 2-dimentional (2D) and 3-dimentional (3D) infrared thermal images of the perovskite film surface. The laser output power and the scanning speed were 150 mW and 25 mm/min respectively. It is noteworthy that only a small local area 321 near the laser beam center shows an apparent higher temperature than the other part of the surface. FIG. 3D shows the temperature distribution along the dash line passing through the laser beam center in FIG. 3B. The maximum temperature of the perovskite surface is 100° C., which is equal to the optimum thermal annealing temperature (i.e. a crystallization temperature of an as-deposited MAPbI₃ perovskite film or substantially close to the crystallization temperature) of a MAPbI₃ perovskite film on a hotplate (See FIGS. 6A-6B). For other laser beams with different wavelengths (405 nm and 660 nm), the central temperatures on perovskite surfaces can also be controlled at the same value by tuning the output power (See FIGS. 7A-7B). Notably, the substrate temperature measured on the back surface is equal to the room temperature because the laser is only absorbed on the top surface of the perovskite film. So the substrate temperature is not increased by the laser annealing, which is critical to some substrates that cannot sustain high temperatures.

FIG. 3E presents the XRD spectra of the thermal-annealed and laser-annealed films (laser wavelength: 450 nm). All diffraction peaks (apart from those peaks from the fluorine doped tin oxide (FTO)/TiO₂ substrate) belong to the MAPbI₃ tetragonal phase, indicating that both films were well crystalized after the annealing processes. The (110) main diffraction peak shows a higher peak intensity than the other peaks corresponding to other lattice planes. The peak intensity ratios of (110) peaks over some other diffraction peaks of the laser-annealed film are much higher than those of the thermal-annealed film (see Table 1), indicating that a preferred orientation along (110) direction has been obtained in the former. Notably, the highly oriented perovskite films prepared by laser annealing are favorable for exciton dissociation, charge transfer and diffusion.

TABLE 1
The intensity ratio of (110) peak over other diffraction
peaks in the XRD spectrum of FIG. 3E.

| Peak intensity ratio | Thermal-annealing | Laser-annealing |
|---|---|---|
| I₍₁₁₀₎/I₍₂₀₀₎ | 11.95 | 21.36 |
| I₍₁₁₀₎/I₍₂₀₂₎ | 13.15 | 16.61 |
| I₍₁₁₀₎/I₍₃₁₀₎ | 3.65 | 5.86 |
| I₍₁₁₀₎/I₍₃₁₄₎ | 13.84 | 15.74 |

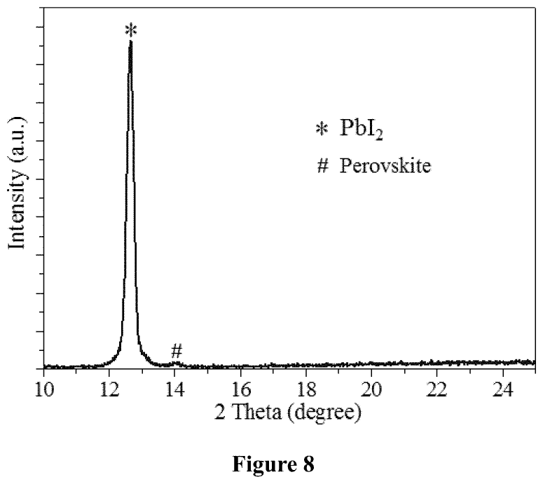

In addition to the annealing of as-deposited perovskite films, the laser scanning system can be used for precisely patterning crystalline perovskite films. As shown in FIG. 3F, the well patterned crystallized perovskite film 34 can be patterned with the laser beam based on a design 35 (See the inset picture) from the control system. When the laser beam is focused on the sample surface to a tiny point, the localized high temperature can decompose the crystalline perovskite film following a reaction of CH₃NH₃PbI₃→PbI₂+CH₃NH₃I (vapor). So a layer of PbI₂ can be obtained after the laser-patterning, as confirmed by the XRD pattern (see FIG. 8). The laser-patterning technique may find applications for large-scale module processing of PSCs or light emitting diodes (LEDs) based on perovskite films.

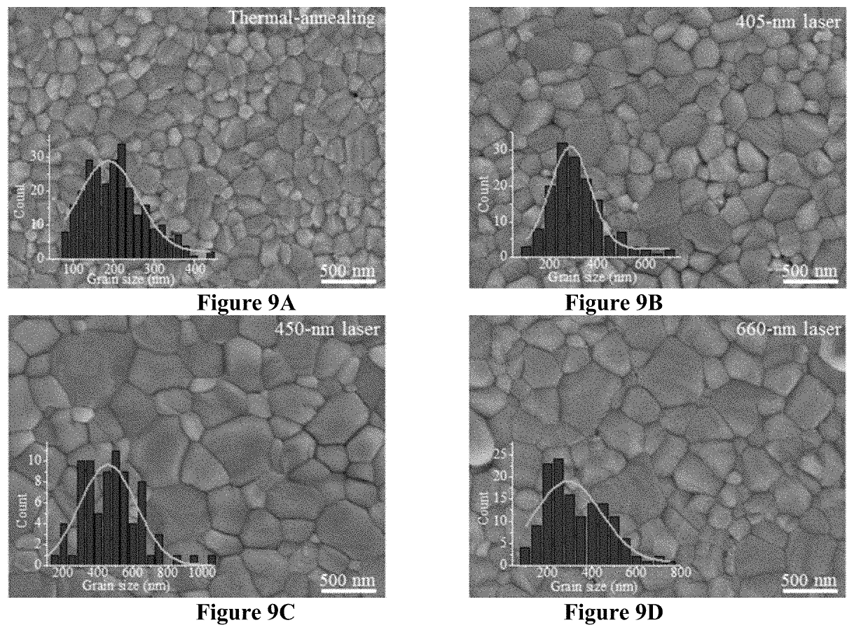

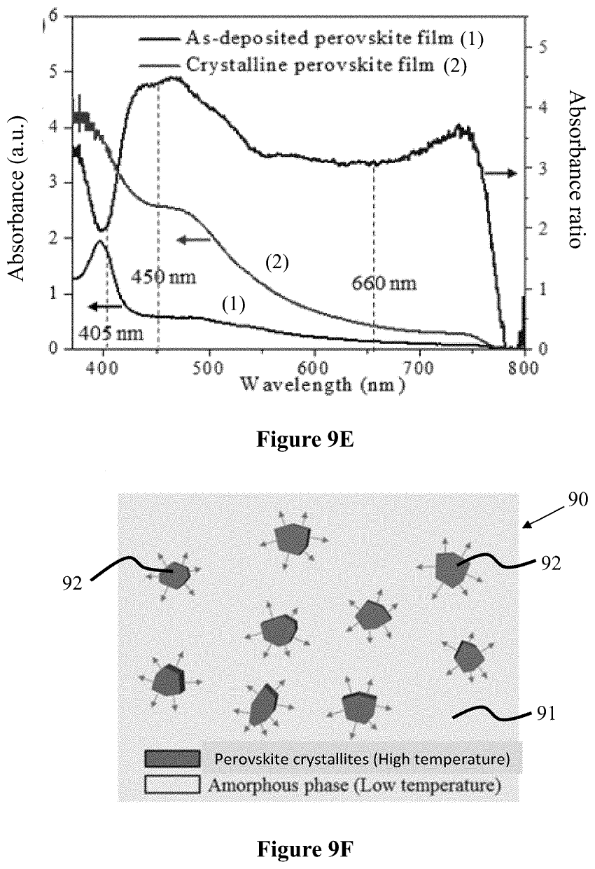

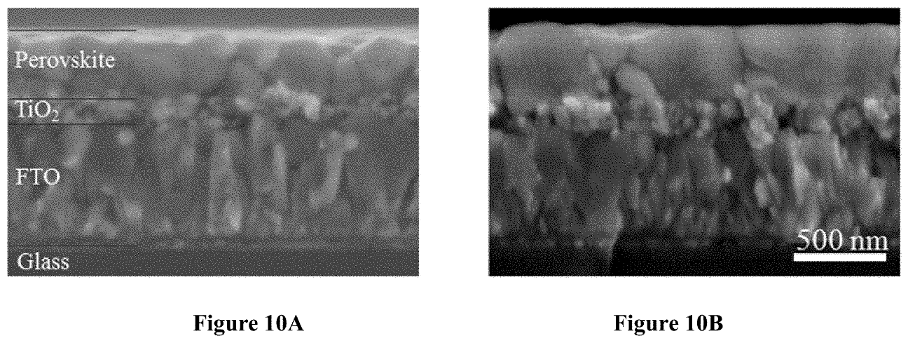

FIGS. 9A-9D shows the plan-view SEM images of the perovskite films fabricated by thermal-annealing and laser-annealing. The statistical diagrams of the grain size distribution based on the SEM images are presented in the insets. Laser beams of different wavelengths (405 nm, 450 nm and 660 nm) were driven at the same scanning speed (25 mm/min) with the same central temperature (100° C.) on perovskite films. The average grain sizes of the laser-annealed perovskite films are much larger than that of the thermal-annealed film. The cross-sectional SEM images of the perovskite films shown in FIGS. 10A-10B also demonstrate that most of the perovskite grains were penetrating through the perovskite capping layer, and most of the grain boundaries were perpendicular to the substrate, which is beneficial for charge transport from perovskite to charge collection layers. Moreover, this microstructure may result in a reduced surface area of the grain boundaries and a low concentration of defects in the perovskite films. So nonradiative charge carrier recombination in the perovskite films can be alleviated, which will lead to enhanced photovoltaic performance of the PSCs.

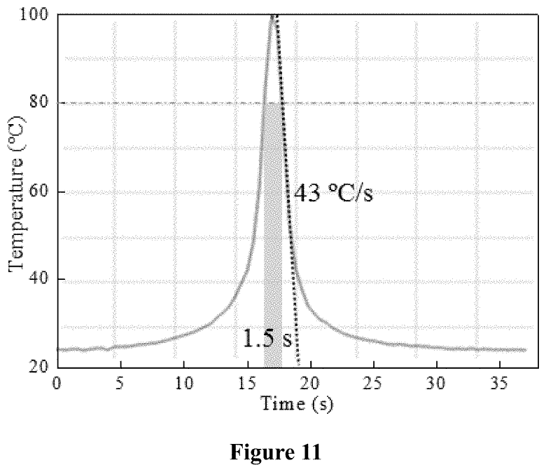

To better understand the laser-annealing effect, UV-visible absorption spectra of the as-deposited and laser-annealed perovskite films were characterized, as presented in FIG. 9E. As shown in FIG. 9F, an as-deposited perovskite film 90 has an amorphous phase 91 and includes a plurality of perovskite crystallites 92, and each of the perovskite crystallite 92 is surrounded by the amorphous phase 91. As shown in FIG. 9E, the light absorption of the crystalline perovskite film is much higher than that of the as-deposited film at any wavelength, indicating that the perovskite crystallites 92 in the as-deposited perovskite film 90 can absorb more energy from the laser and have higher temperatures than the surrounding amorphous phase 91, as illustrated in FIG. 9F. The laser spot was scanned on the surface with a high speed (25 mm/min), the actual annealing time for each point is estimated to be 1.5 s (See FIG. 11). Notably, the surface temperature can be increased to 100° C. in a few seconds with the rate up to 43° C./s. During the fast laser annealing process, localized temperature gradient on the boundaries of perovskite crystallites can be generated, which acts as a driving force for the growth of perovskite crystallites. The crystallites can absorb more energy and have higher temperatures than the amorphous phase, which can induce the selective growth of the crystallites. However, for thermal-annealing, heat is transferred from the bottom glass/FTO/TiO₂ substrate to the upper perovskite film, and it can be uniformly absorbed by both the crystalline and the amorphous phases of the perovskite film, leading to a high density of nucleation seeds in the films upon annealing. Therefore, the fast laser-annealing approach can result in larger grains than the thermal annealing process.

Notably, the crystallinity of the laser-annealed perovskite films is closely related to the laser wavelength. The average grain sizes were different when three different lasers (wavelength: 405 nm, 450 nm and 660 nm) were used in the annealing processes and 450-nm laser led to the largest average grain size of ˜476 nm (See Table 2). This effect can be attributed to the different light absorption coefficients of the perovskite films at different wavelengths. It is noteworthy that the absorbance ratio of the two absorption spectra shown in FIG. 9E changes with the light wavelength and peaks at around 450 nm. Therefore, the 450-nm laser can induce the biggest temperature gradient on grain boundaries in perovskite films and provide the largest growth driving force for the perovskite crystallites in the as-deposited film.

TABLE 2
The average grain size calculated
based on SEM images in FIG. 9A-9D.

| Annealing | Laser | Average grain size |
|---|---|---|
| methods | wavelengths | (nm) |
| Thermal-annealing | — | 206 |
| Laser-annealing | 405 nm | 313 |
| | 450 nm | 476 |
| | 660 nm | 333 |

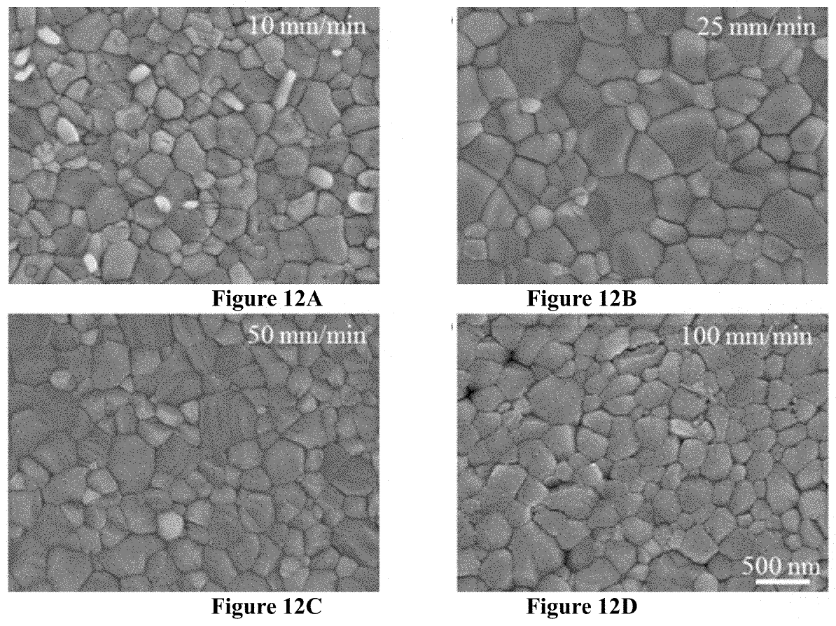

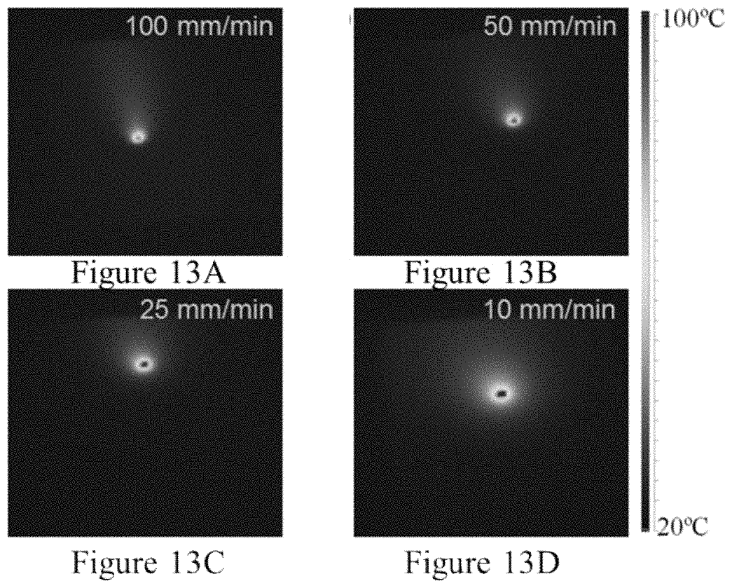

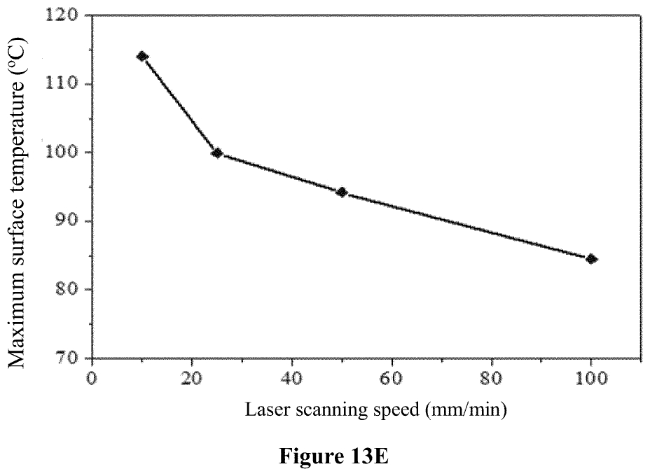

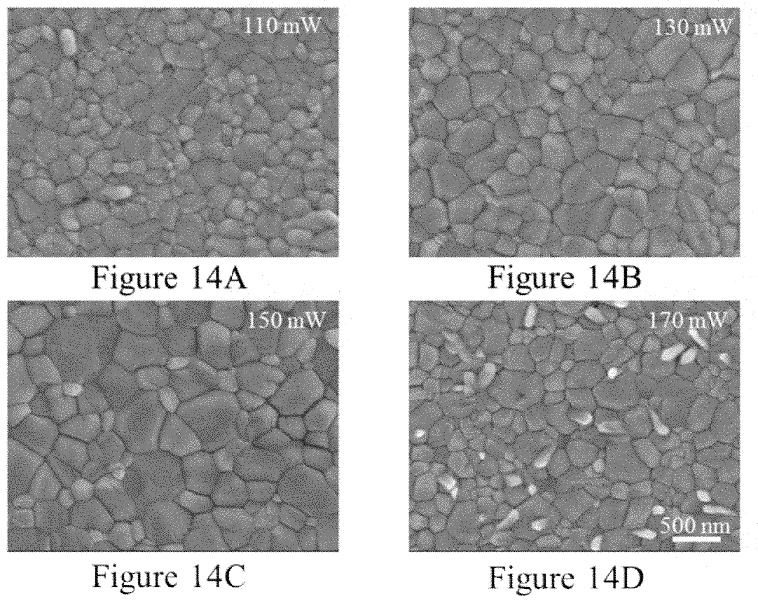

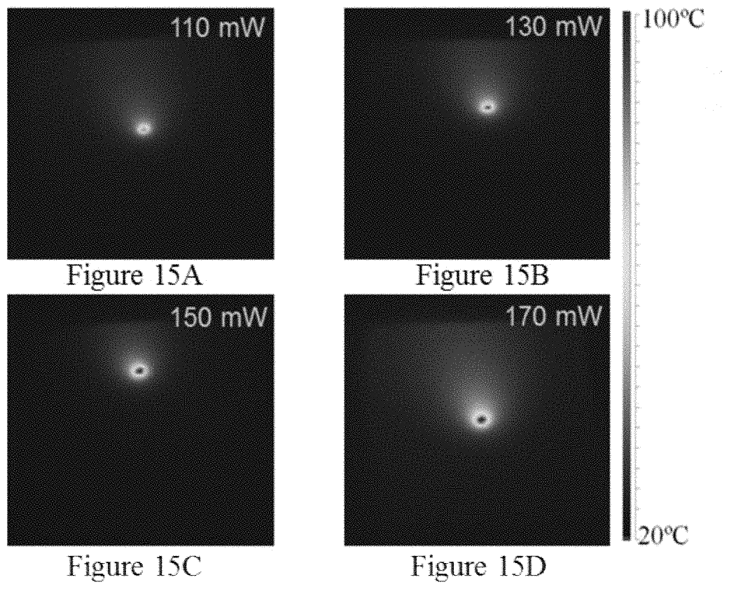

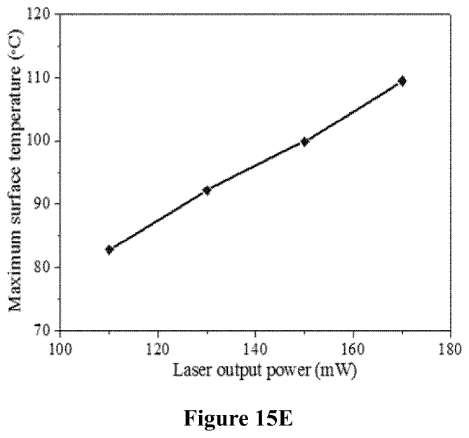

The influence of scanning speed and laser output power on the morphology of the perovskite films was studied. For the fixed power (150 mW) of the laser, the grain size increased with the decrease of scanning speed and then decreased when the speed was less than 25 mm/min (see FIGS. 12A-12D). The surface temperature increased with the decrease of scanning speed and the largest grain size was obtained when the central temperature was 100° C. (see FIGS. 13A-13E). For a fixed scanning speed of 25 mm/min, the crystallinity increased with the increase of output power and then decreased when the power was over 150 mW (see FIGS. 14A-14D). The corresponding surface temperature as a function of output power was also obtained (see FIGS. 15A-15D). Both experiments indicated that the maximum grain size was achieved at the central temperature of 100° C., which is consistent with the condition required by a thermal annealing process.

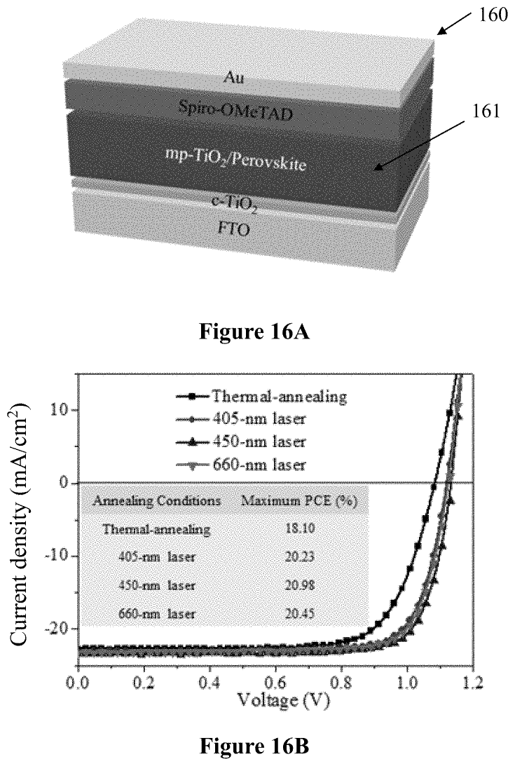

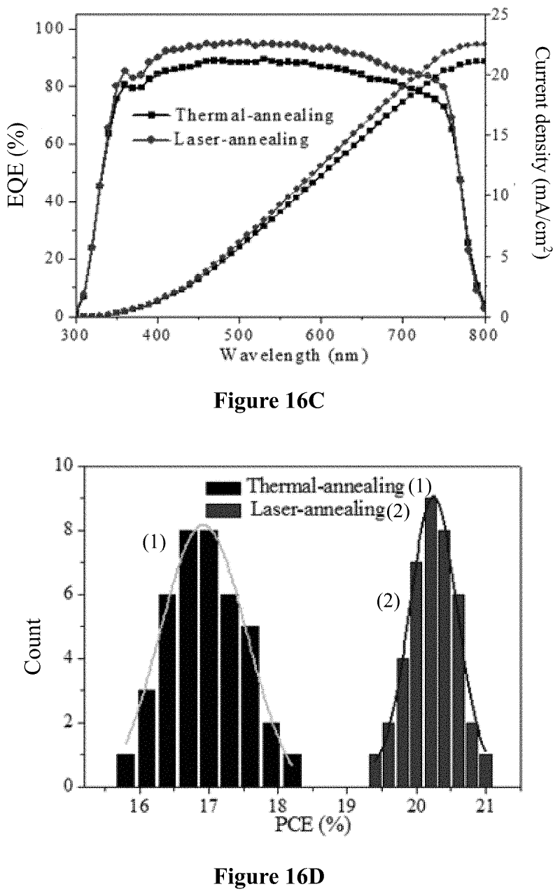

PSCs 160 were prepared with a device configuration of glass/FTO/compact TiO₂ (c-TiO₂)/mesoporous TiO₂ (mp-TiO₂)/perovskite 161/spiro-OMeTAD/Au, as shown in FIG. 16A. Current density-voltage (J-V) curves of the devices prepared by laser-annealing and thermal-annealing (control) processes are presented in FIG. 16B. The detailed photovoltaic parameters of the PSCs are summarized in Table 3. All parameters are considerably improved for the PSCs fabricated by laser-annealing processes in comparison with the control devices processed by thermal annealing. The control devices show an average PCE of 16.89%, V_{oc} of 1.069 V, short circuit current density (J_{sc}) of 22.36 mA/cm² and fill factor (FF) of 70.64%. In contrast, the 405-nm laser treated devices show an enhanced average PCE of 19.71%, V_{oc} of 1.112 V, J_{sc} of 23.18 mA/cm² and FF of 76.44%. The average efficiency is further increased to 19.92% with V_{oc} of 1.119 V, J_{sc} of 23.22 mA/cm², and FF of 76.68% by using 660-nm laser. The device performance is maximized when 450-nm laser is adopted, demonstrating an average PCE of 20.23%, V_{oc} of 1.124 V, J_{sc} of 23.29 mA/cm² and FF of 77.27%. The greatly enhanced device performance by laser annealing is consistent with the improved crystallinity of the laser-annealed perovskite films. Notably, the champion device by laser-annealing shows PCE of 20.98% (19.90%), V_{oc} of 1.13 V (1.125 V), J_{sc} of 23.41 mA/cm² (23.41 mA/cm²) and FF of 79.3% (75.5%) for reverse (forward) scan. FIG. 16C presents the corresponding EQE spectra, demonstrating an improved quantum efficiency in the whole wavelength range for the champion device. The integrated photocurrent from the EQE spectra is in good agreement with the J_{sc} derived from the J-V curves in FIG. 16B.

TABLE 3
Photovoltaic parameters of MAPbI₃ PSCs fabricated by thermal-annealing
and laser-annealing (with different laser wavelengths) processes.
(Average of no less than 20 cells for each condition.)

| | Laser | V_{OC} | J_{SC} | | | Champion |
|---|---|---|---|---|---|---|
| | wavelengths | (V) | (mA/cm²) | FF (%) | PCE (%) | PCE (%) |
| Thermal- | — | 1.069 ± 0.011 | 22.36 ± 0.47 | 70.64 ± 2.02 | 16.89 ± 0.72 | 18.10 |
| annealing | | | | | | |
| Laser- | 405 nm | 1.112 ± 0.009 | 23.18 ± 0.21 | 76.44 ± 1.24 | 19.71 ± 0.38 | 20.23 |
| annealing | 450 nm | 1.124 ± 0.009 | 23.29 ± 0.20 | 77.27 ± 1.16 | 20.23 ± 0.35 | 20.98 |
| | 660 nm | 1.119 ± 0.008 | 23.22 ± 0.21 | 76.68 ± 1.17 | 19.92 ± 0.38 | 20.45 |

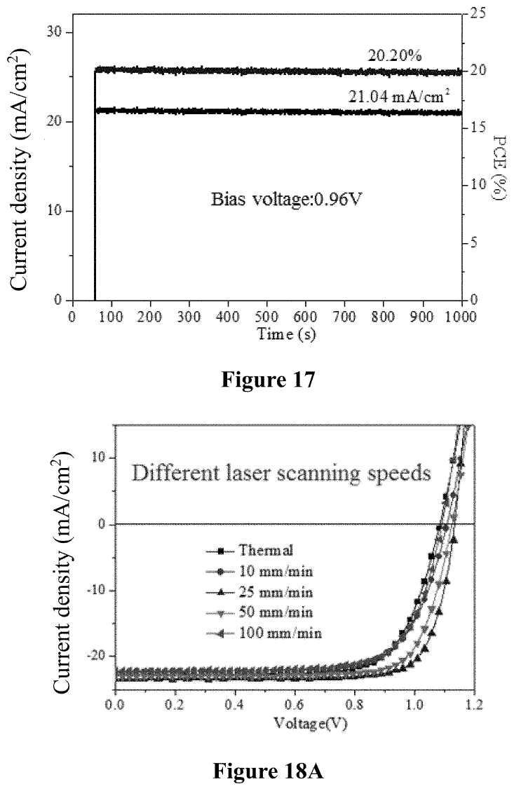

For the champion device, a steady-state efficiency of 20.20% was achieved at the maximum power point of 0.96 V (See FIG. 17). Besides, the statistical data of devices (40 devices for each condition) prepared by using the optimized laser-annealing and thermal-annealing approaches, respectively were collected, as shown in FIG. 16D. The target devices have an average efficiency of 20.23%, which is much higher than that of the control devices (16.89%). It is notable that the PCEs of the target devices are distributed in a narrow range from 19.41% to 20.98%, showing good reproducibility.

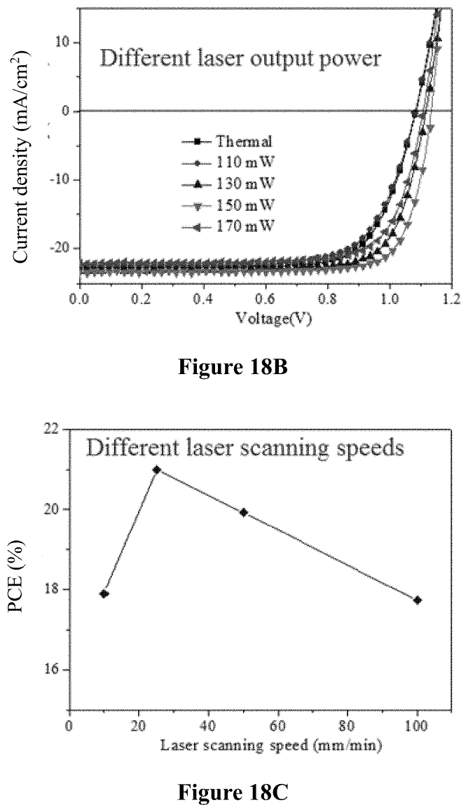

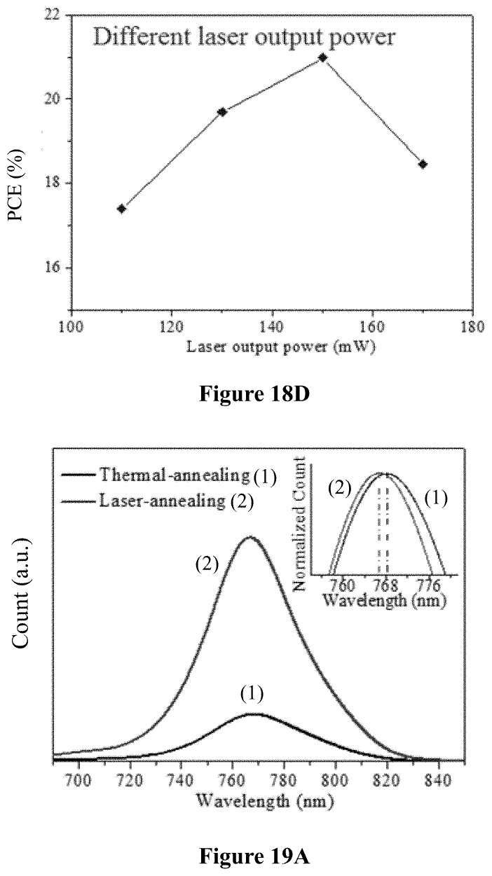

The influences of the laser scanning speeds and laser output power on the device performance were investigated (with laser wavelength: 450 nm) (See FIGS. 18A-18D and Tables 4-5). The effects of laser scanning speed and laser power on the device performance were quite similar. With the increase of the laser scanning speeds from 10 mm/min to 100 mm/min (or the laser output power from 110 mW to 170 mW), the average PCEs were firstly increased and subsequently decreased with a maximum value of 20.23% at the scanning speed of 25 mm/min and the laser power of 150 mW, which is consistent with the condition for obtaining the biggest perovskite grain size. These results suggest that the photovoltaic performance of the PSCs is closely related to the crystallinity of the laser-annealed perovskite films.

TABLE 4
Photovoltaic parameters of MAPbI₃ PSCs fabricated at different laser scanning
speeds, 450-nm laser was used, and the laser output power was 150 mW.

| Annealing | Laser scanning | V_{OC} | J_{SC} | | | Champion |
|---|---|---|---|---|---|---|
| methods | speed (mm/min) | (V) | (mA/cm²) | FF (%) | PCE (%) | PCE (%) |
| Thermal- | — | 1.069 ± 0.011 | 22.36 ± 0.47 | 70.64 ± 2.02 | 16.89 ± 0.72 | 18.10 |
| annealing | | | | | | |
| Laser- | 10 | 1.099 ± 0.011 | 21.93 ± 0.32 | 71.21 ± 1.29 | 17.16 ± 0.41 | 17.91 |
| annealing | 25 | 1.124 ± 0.009 | 23.29 ± 0.20 | 77.27 ± 1.16 | 20.23 ± 0.35 | 20.98 |
| | 50 | 1.106 ± 0.011 | 23.08 ± 0.25 | 75.85 ± 1.25 | 19.37 ± 0.43 | 19.93 |
| | 100 | 1.077 ± 0.011 | 21.85 ± 0.40 | 73.08 ± 1.30 | 17.20 ± 0.38 | 17.74 |

TABLE 5
Photovoltaic parameters of MAPbI₃ PSCs fabricated at different laser output
power, 450-nm laser was used, and the laser scan speed was 25 mm/min.

| Annealing | Laser output | V_{OC} | J_{SC} | | | Champion |
|---|---|---|---|---|---|---|
| methods | power (mW) | (V) | (mA/cm²) | FF (%) | PCE (%) | PCE (%) |
| Thermal- | — | 1.069 ± 0.011 | 22.36 ± 0.47 | 70.64 ± 2.02 | 16.89 ± 0.72 | 18.10 |
| annealing | | | | | | |
| Laser- | 110 | 1.078 ± 0.011 | 22.05 ± 0.23 | 69.76 ± 1.48 | 16.58 ± 0.43 | 17.39 |
| annealing | 130 | 1.104 ± 0.013 | 23.04 ± 0.25 | 75.15 ± 1.03 | 19.12 ± 0.41 | 19.69 |
| | 150 | 1.124 ± 0.009 | 23.29 ± 0.20 | 77.27 ± 1.16 | 20.23 ± 0.35 | 20.98 |
| | 170 | 1.100 ± 0.011 | 21.82 ± 0.24 | 74.12 ± 1.31 | 17.79 ± 0.50 | 18.46 |

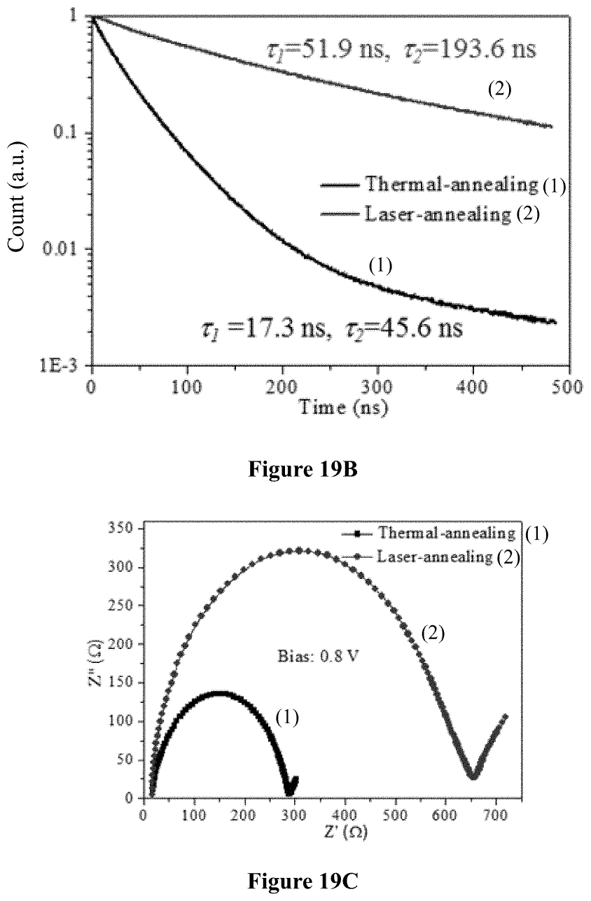

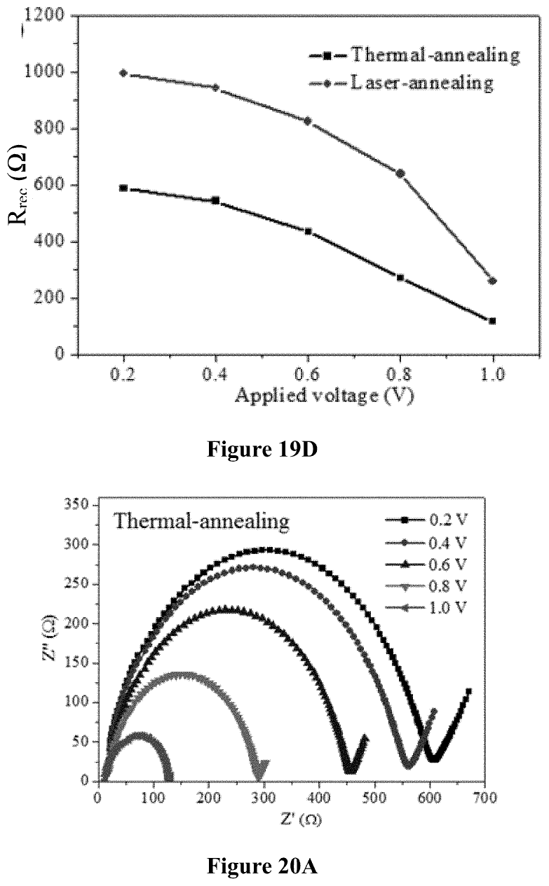

To gain a deeper insight into the nature of the outstanding photovoltaic performance of the PSCs prepared by laser-annealing approach, steady-state and time-resolved photoluminescence (PL) measurements of the perovskite films prepared at different conditions were performed, as shown in FIGS. 19A and 19B. The perovskite films for PL measurements were fabricated on pure glass substrates without FTO layers. It is notable that the optimized laser-annealed perovskite film exhibited more than three-fold increase in PL intensity relative to that of the thermal-annealed film. Meanwhile, the PL peak demonstrated a slight blue shift from 768 nm (thermal-annealing) to 766 nm (laser-annealing). The enhanced PL intensity and the blue-shifted PL peak stem from the decreased bulk defect density in the perovskite absorber, which can lead to reduced charge recombination. To analyze the dynamics of the charge recombination in the perovskite films, time-resolved PL decay measurements were also performed. The PL decay processes for thermal-annealed and laser-annealed perovskite films are shown in FIG. 19B. A much slower PL decay can be found in the laser-annealed film. The decay curves were fitted with a biexponential function: Y=A₁ exp (−t/τ₁)+A₂exp(−t/τ₂). The fast decay lifetime (τ₁) was attributed to the nonradiative recombination in the region with high-density defects such as the film surface, while the slow decay lifetime (τ₂) was ascribed to the recombination in the region with lower density of defects. The laser-annealed perovskite film displayed the two decay lifetimes of τ₁=51.9 ns and τ₂=193.6 ns. In contrast, the thermal-annealed film exhibited much shorter lifetimes: τ=17.3 ns and τ₂=45.6 ns. The longer PL lifetimes of the laser-annealed perovskite films imply the decreased concentrations of defects and traps, which can result in an increased short-circuit current and a higher open-circuit voltage of a PSC.

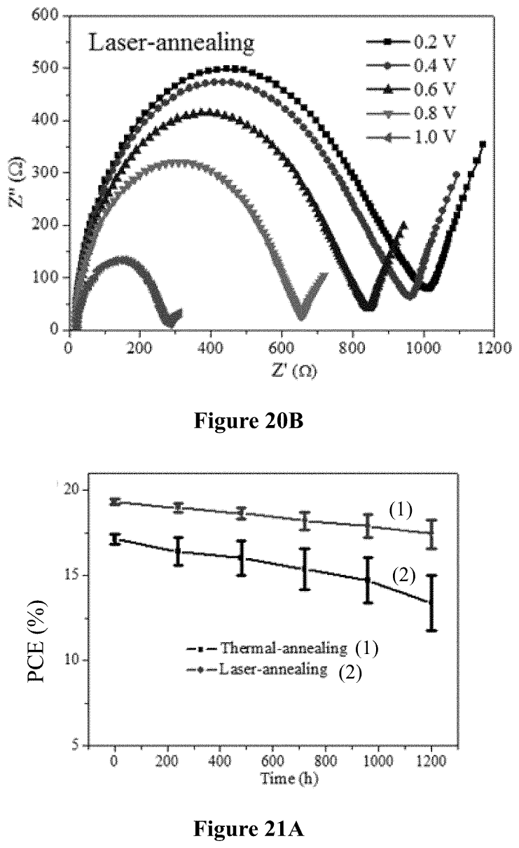

Electrochemical impedance spectroscopy (EIS) measurements of the PSCs were performed under light illumination of 100 mW/cm². FIG. 19C shows the EIS spectra of the devices at a bias voltage of 0.8 V. A big half circle corresponding to charge recombination process can be found in the Nyquist plot. The target device exhibits a much larger recombination resistance (˜639.6Ω) than that of the control device (˜271.3Ω), indicating reduced charge recombination in the perovskite films or at the interfaces between perovskite and charge transport layers. FIG. 19D shows the recombination resistance (R_{rec}) values at different applied voltages under light illumination of 100 mW/cm² (derived from the impedance spectra in FIGS. 20A-20B). It is notable that R_{rec} was larger for the target device at any bias voltage than that for the control device, indicating a slower recombination rate in the target device, which can be attributed to the lower density of trap states in the laser-annealed perovskite film. Furthermore, the increased R_{rec} will contribute to the shunt resistance of the solar cells, which is a main reason for the increased FF of the target devices.

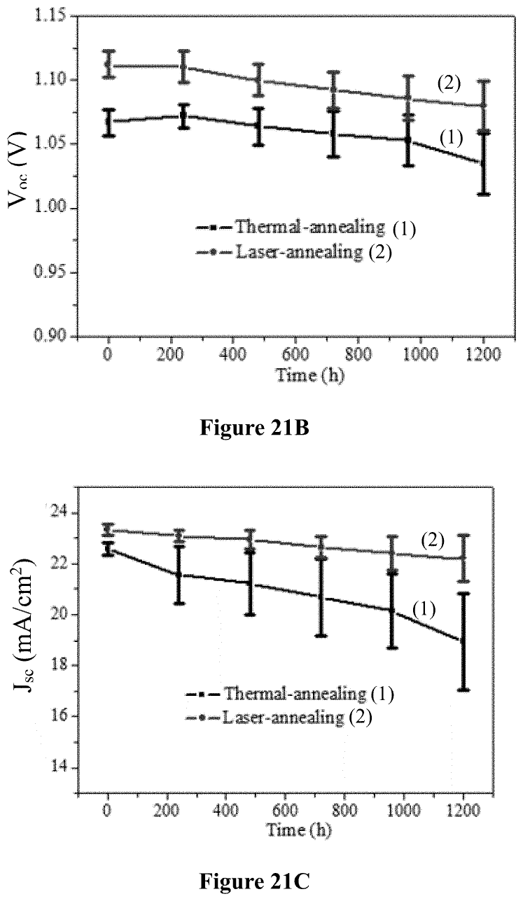

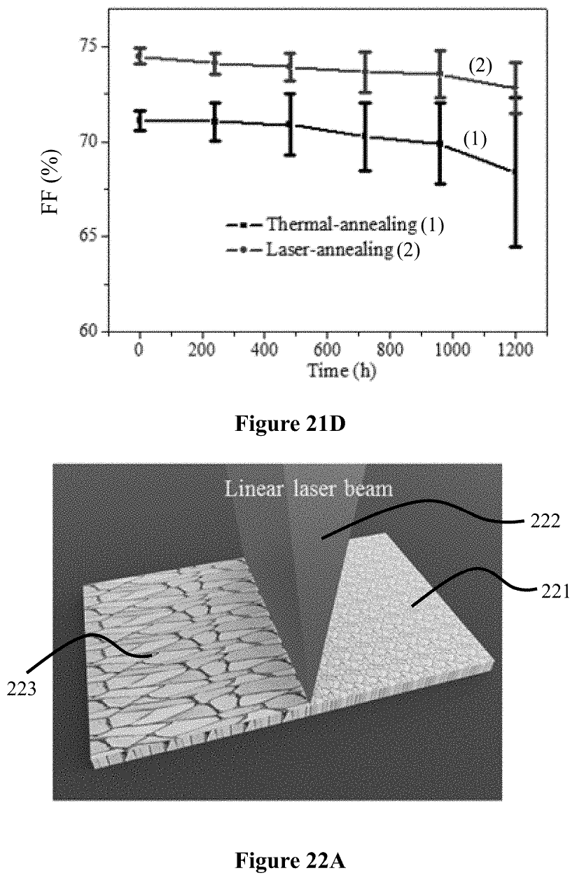

The long-term stability of the PSCs fabricated by laser-annealing and thermal-annealing processes were investigated. The encapsulated devices were kept in air with a relative humidity ˜30% for stability study. J-V curves of the devices were characterized for every 240 h. The statistical data of the PCEs after degradation for 1200 h was shown in FIG. 21A-21D. Apparently, the devices fabricated by laser-annealing are much more stable than the control devices. The target devices maintained about 90% of its initial average PCE after the storage for 1200 h, while the control devices retained only 78% of the original efficiency. The improved stability of the target devices can be attributed to the improved crystallinity of the laser-annealed perovskite films.

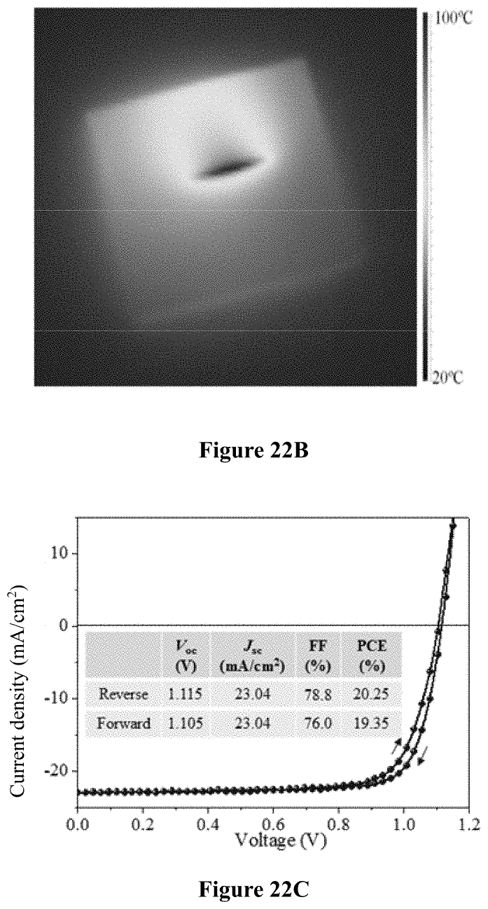

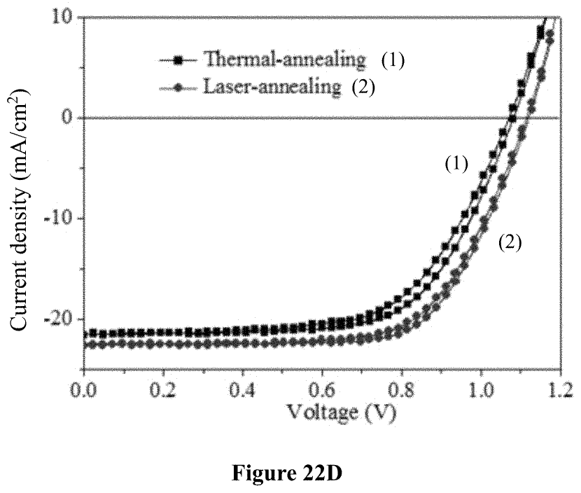

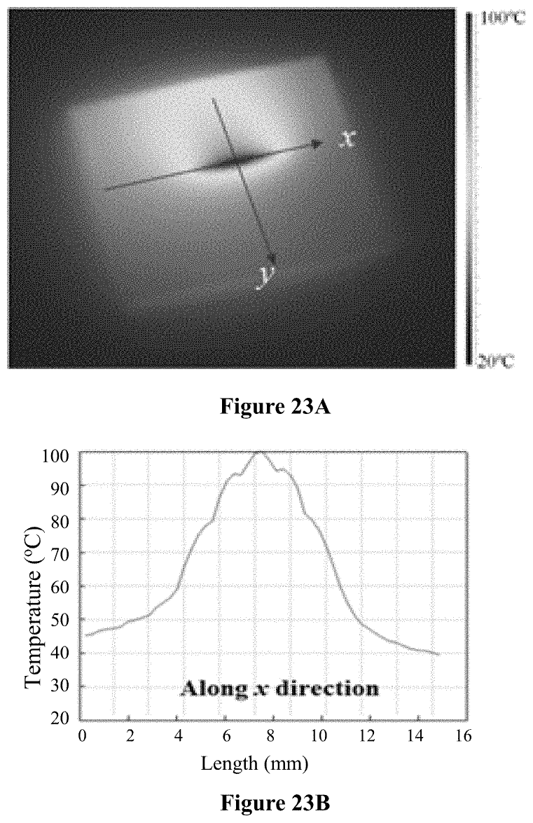

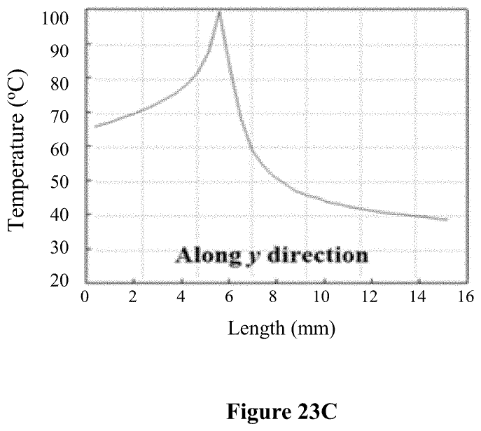

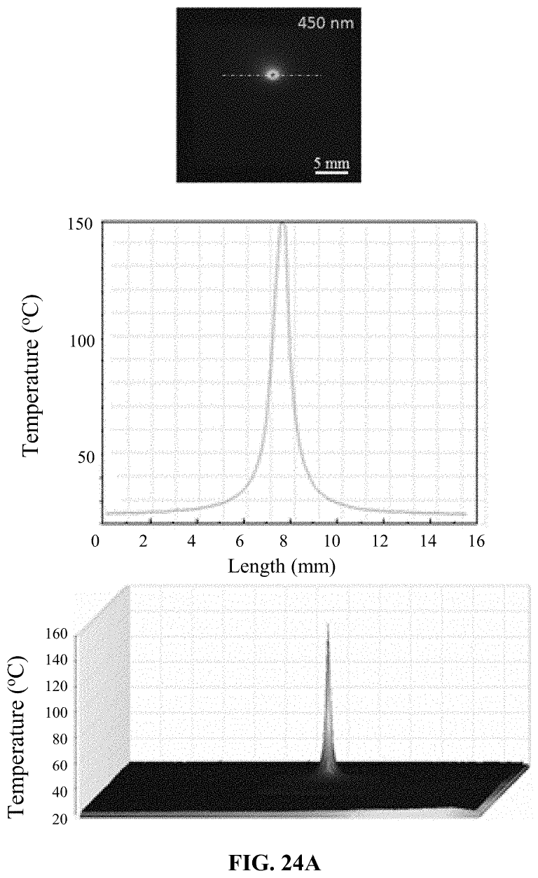

To realize faster laser annealing of perovskite films, linear laser beams were used according to certain embodiments, which were generated by introducing a cylindrical convex lens. FIG. 22A shows the schematic diagram of the laser annealing process of the as-deposited perovskite film 221 by using a linear laser beam 222 for converting the as-deposited perovskite film 221 into a laser-annealed perovskite film 223. FIG. 22B shows the infrared thermal image of the as-deposited perovskite film surface during linear laser scanning (wavelength: 450 nm, step distance: 2 mm). The temperature distribution close to the linear laser beam along two vertical directions is shown in FIGS. 23A-23C. The high temperature region (>70° C.) is about 5 mm. So it is much faster to anneal a sample by using the linear laser than a laser spot. The J-V curve of the champion small-area PSC prepared by the linear laser annealing is shown in FIG. 22C. The device shows a high efficiency of 20.25%, V_{oc} of 1.115 V, J_{sc} of 23.04 mA/cm², and FF of 78.8% (derived from the reverse scan curve). By using this linear laser scanning process, large-area PSCs were prepared with an active area of 1.0 cm². The corresponding J-V curves of the laser-annealed PSCs are shown in FIG. 22D. The laser-annealed PSC exhibits a relatively high efficiency of 17.26%, which is 13.7% higher than that of the thermal-annealed device (15.18%), as shown in Table 6. For a device with the size of 1 cm×1 cm, the laser-annealing time is estimated to be ˜24 s, which is much shorter than the conventional thermal-annealing time on a hotplate (tens of minutes). Importantly, this technique can be scaled up for a much higher throughput simply by using more or bigger laser sources. In addition, the power consumption for laser-annealing can be far less than that of thermal-annealing. Therefore, the cheap and fast laser-annealing technique is promising for the large-scale fabrication of high-efficiency PSCs.

TABLE 6
Photovoltaic parameters of the large-
area MAPbI₃ PSCs (area: 1.0 cm²).

| Annealing | Scan | L_{OC} | J_{SC} | FF | PCE |
|---|---|---|---|---|---|
| methods | directions | (V) | (mA/cm²) | (%) | (%) |
| Thermal | Reverse | 1.08 | 21.57 | 65.1 | 15.18 |
| annealing | Forward | 1.07 | 21.57 | 62.2 | 14.36 |
| Laser | Reverse | 1.12 | 22.60 | 68.2 | 17.26 |
| annealing | Forward | 1.115 | 22.60 | 66.0 | 16.62 |

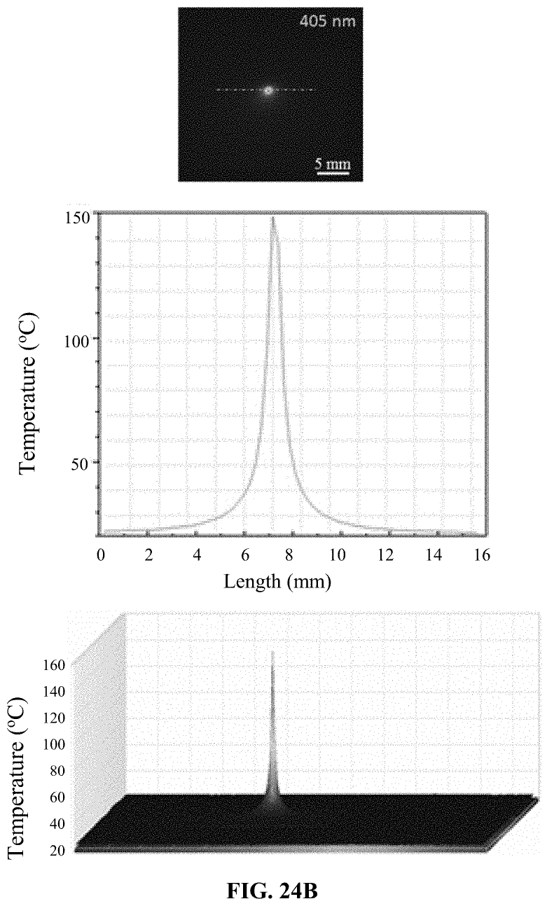

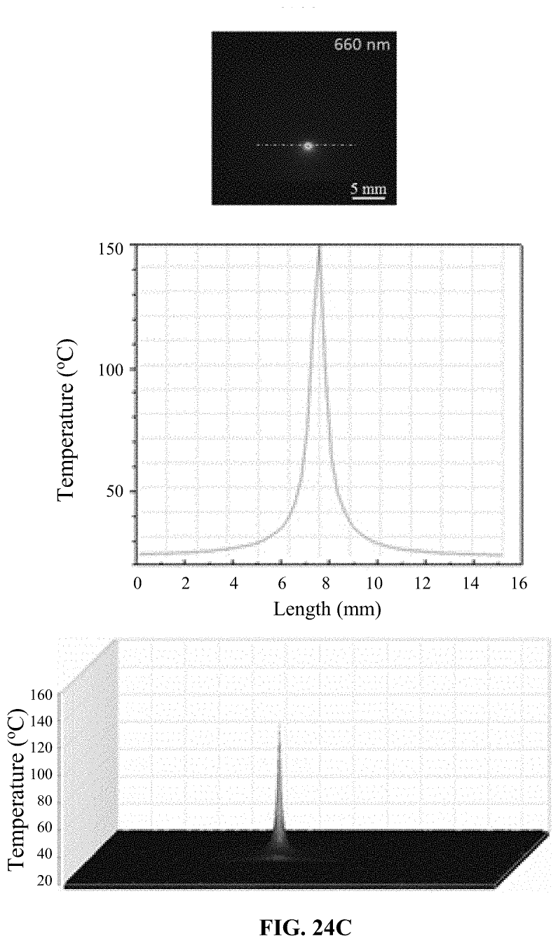

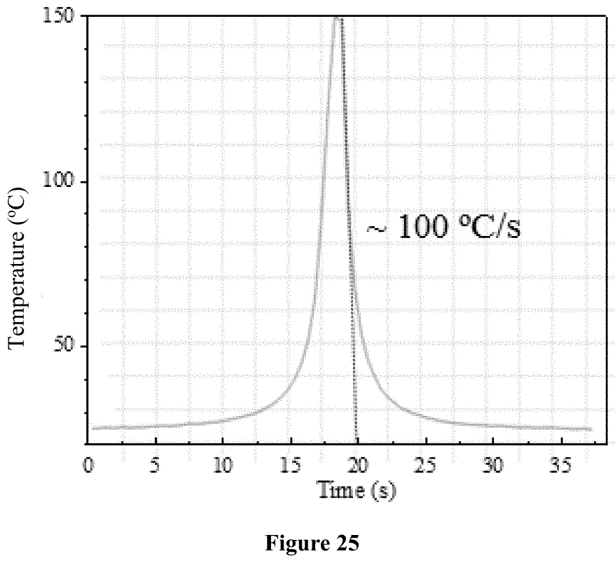

In addition to the MAPbI₃-based PSCs, (CsPbI₃)_{0.05}(FAPbI₃)_{0.95}(MAPbBr₃)_{0.05} mixed PSCs were also prepared by using laser-annealing approach. The as-deposited mixed perovskite films were annealed by scanning laser beams with wavelengths of 405 nm, 450 nm or 660 nm. The surface temperature distribution of the mixed perovskite film was monitored by the infrared thermal imager (See FIGS. 24A-24C). Mixed PSCs were then prepared with the same device structure as the above mentioned MAPbI₃-based PSCs. The device performance was then optimized by controlling the laser power. Under the optimum conditions, the maximum surface temperatures of the perovskite films are all close to 150° C. (equal to the optimum thermal-annealing temperature of the control device). Similarly, only a very small area of the perovskite film surface near the beam center shows relatively high temperature, while the surface temperature of the other part of the film is close to the room temperature. The maximum heating rate is about 100° C./s, which cannot be achieved by a normal thermal annealing method (See FIG. 25).

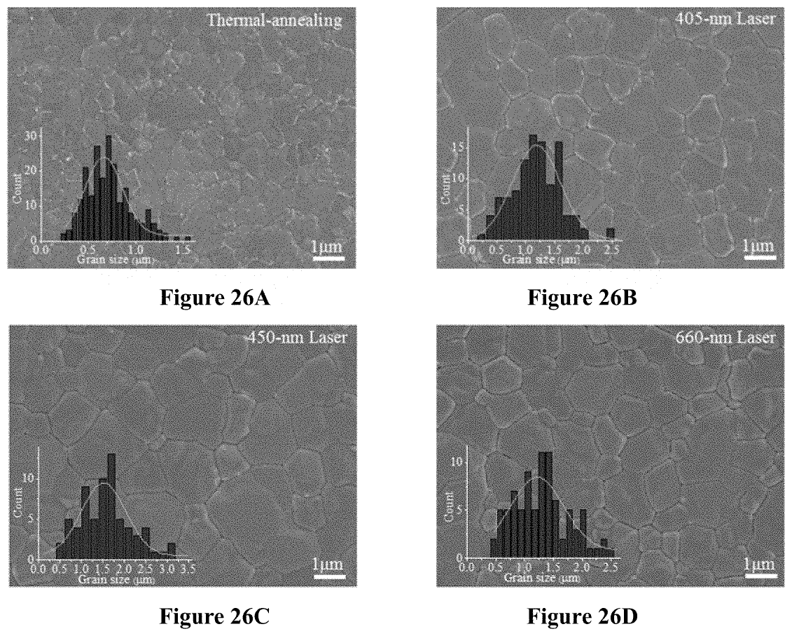

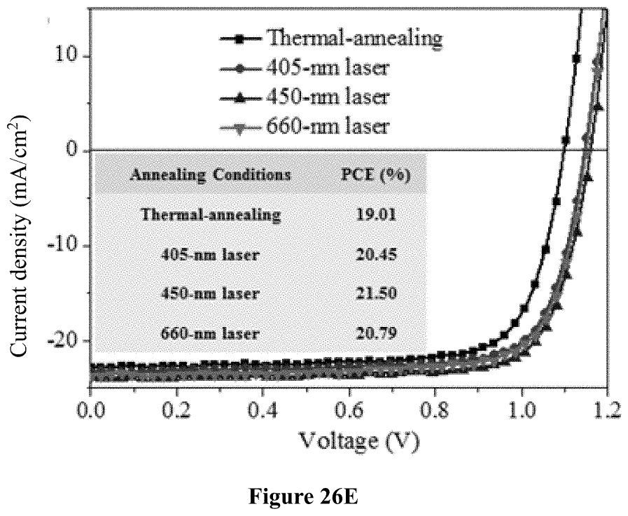

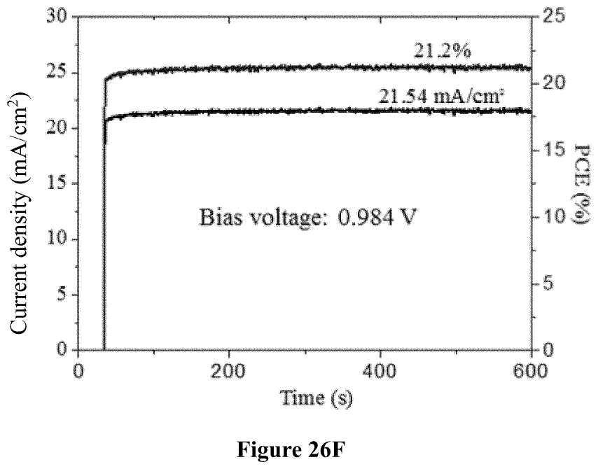

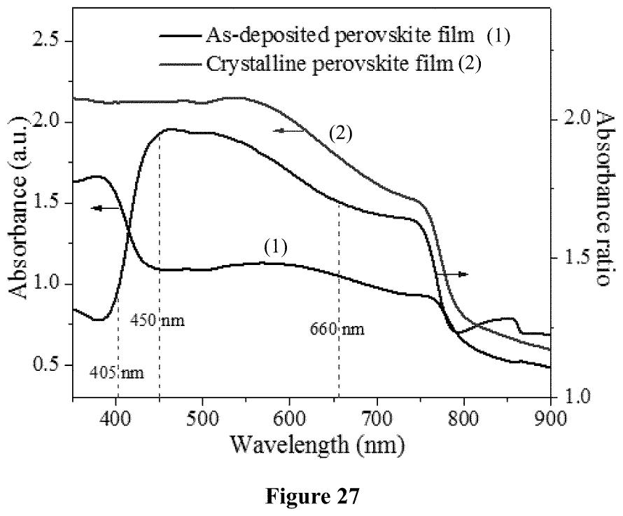

FIGS. 26A-26D show the SEM images of the mixed perovskite films prepared by thermal-annealing (150° C. for 10 min) and laser-annealing processes. The average grain sizes of the laser-annealed perovskite films (1.84 μm for 450-nm laser, 1.5 μm for 660-nm laser, and 1.38 μm for 405-nm laser) are much larger than that of the control film prepared by thermal-annealing (0.88 μm) (See Table 7), which is consistent with the result of MAPbI₃ perovskite films. More importantly, the grain size is closely related with the laser wavelength. Therefore, the UV-visible absorbance spectra of the as-deposited and laser-annealed mixed perovskite films were checked (See FIG. 27). Notably, the absorbance ratio between the two films varies with the light wavelength and peaks at around 450 nm. At this condition, the average grain size is the maximum, which further confirms that the temperature gradient in the film is critical to the selective growth of perovskite crystallites. As explained above, the 450-nm laser can provide the largest growth driving force for the perovskite crystallites in the as-deposited films. As a result, perovskite films annealed with 450-nm laser show largest average grain size.

TABLE 7
The average grain size calculated based
on SEM images in FIGS. 26A-26D.

| Annealing | Laser | Average grain size |
|---|---|---|
| methods | wavelengths | (μm) |
| Thermal-annealing | — | 0.88 |
| Laser-annealing | 405 nm | 1.38 |
| | 450 nm | 1.84 |
| | 660 nm | 1.50 |

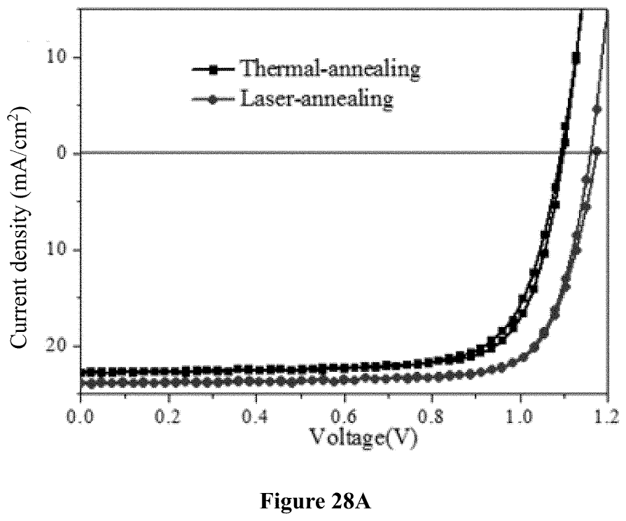

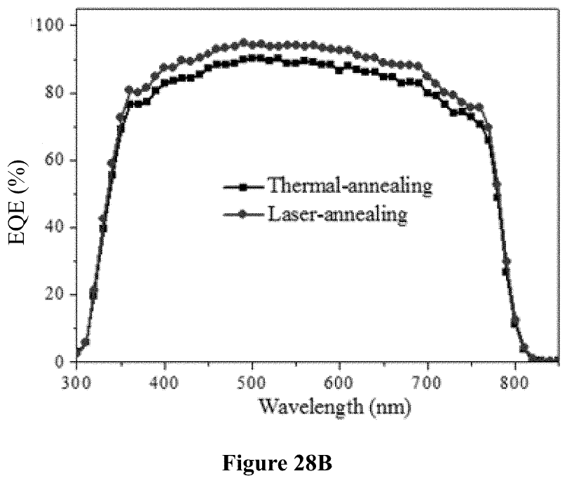

FIG. 26E shows the J-V curves of the devices fabricated by thermal-annealing and laser-annealing processes. Detailed photovoltaic parameters are summarized in Table 8. Notably, the device performance is better for the devices with larger perovskite grains. A high V_{oc} of 1.175 V and high PCE of 21.5% were achieved when 450-nm laser was used for the laser-annealing process. The champion device can get a steady-state efficiency of 21.2%, as shown in FIG. 26F. Moreover, the optimized devices also show negligible hysteresis and increased quantum efficiency (See FIGS. 28A-28B and Table 9).

TABLE 8
Photovoltaic parameters of the mixed PSCs fabricated by thermal-annealing and laser-
annealing processes. (Average of no less than 20 cells for each condition.)

| | Laser | V_{OC} | J_{SC} | | | Champion |
|---|---|---|---|---|---|---|
| | wavelengths | (V) | (mA/cm²) | FF (%) | PCE (%) | PCE (%) |
| Thermal- | — | 1.09 ± 0.01 | 22.83 ± 0.46 | 73.10 ± 1.18 | 18.22 ± 0.46 | 19.01 |
| annealing | | | | | | |
| Laser- | 405 nm | 1.13 ± 0.01 | 23.56 ± 0.34 | 76.60 ± 0.84 | 20.19 ± 0.32 | 20.45 |
| annealing | 450 nm | 1.14 ± 0.01 | 23.56 ± 0.21 | 77.44 ± 0.69 | 20.82 ± 0.31 | 21.50 |
| | 660 nm | 1.14 ± 0.01 | 23.40 ± 0.26 | 76.68 ± 0.65 | 20.44 ± 0.30 | 20.79 |

TABLE 9
Photovoltaic parameters of the best mixed PSCs.

| Annealing | Scan | L_{OC} | J_{SC} | FF | PCE |
|---|---|---|---|---|---|
| methods | directions | (V) | (mA/cm²) | (%) | (%) |
| Thermal | Reverse | 1.10 | 22.80 | 75.8 | 19.01 |
| annealing | Forward | 1.095 | 22.80 | 74.3 | 18.55 |
| Laser | Reverse | 1.160 | 23.85 | 77.6 | 21.47 |
| annealing | Forward | 1.175 | 23.85 | 76.7 | 21.50 |
| (450-nm laser) | | | | | |

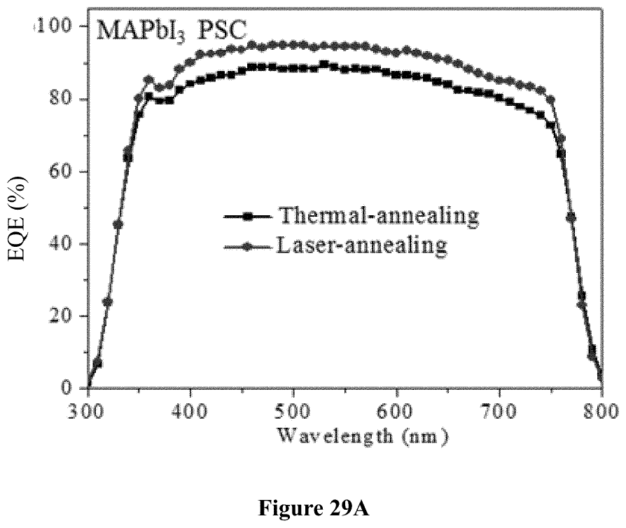

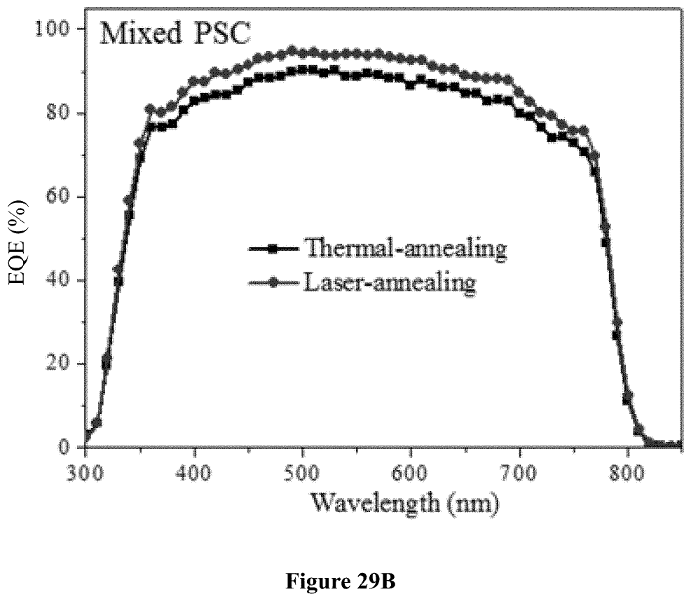

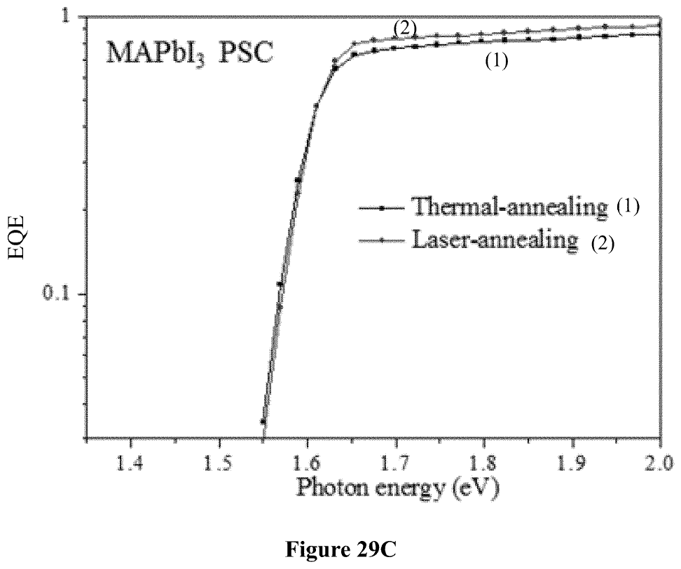

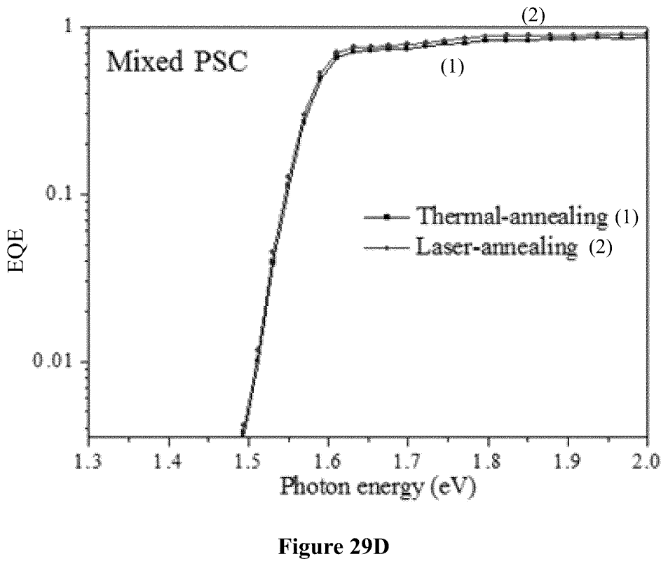

The quality of the perovskite films can be reflected by the Urbach energy (Eᵤ), which is normally related to the impurities, ionic disorder and atomic vibrational fluctuations in the films. The Urbach energy were calculated according to the EQE spectra of the best MAPbI₃ and mixed PSCs (See FIGS. 29A-29D). Based on the equation of EQE=EQE₀ exp [(E−E_{g})/Eᵤ] (where EQE₀ is the EQE value at the bandgap), the slope of the exponential EQE tail defines the Urbach energy. The derived Urbach energy values are shown in Table 10. Notably, both MAPbI₃ and mixed PSCs prepared by laser-annealing technique show slightly lower Urbach energies (18.3 meV and 14.2 meV) than those obtained from thermal-annealing method (19.8 meV and 15.7 meV), indicating better quality of the laser-annealed perovskite films, which leads to the increased V_{oc} of the PSCs prepared by laser-annealing processes.

TABLE 10
The Urbach energy (Eᵤ) values derived from the EQE curves.

| Solar cells | Annealing method | Eᵤ (meV) |
|---|---|---|
| MAPbI₃ PSCs | Thermal-annealing | 19.8 |
| | Laser-annealing | 18.3 |
| Mixed PSCs | Thermal-annealing | 15.7 |
| | Laser-annealing | 14.2 |

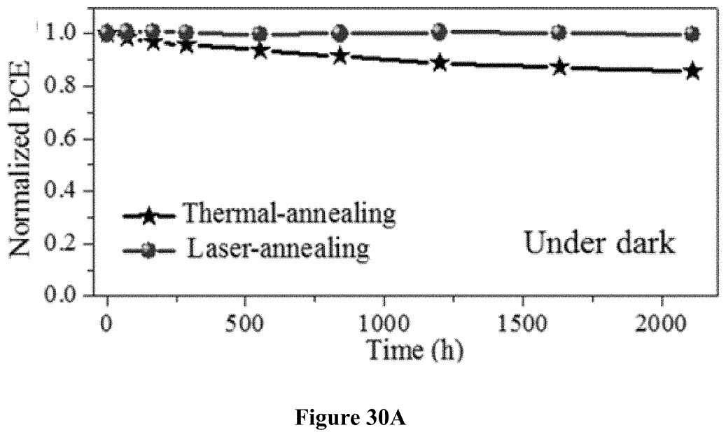

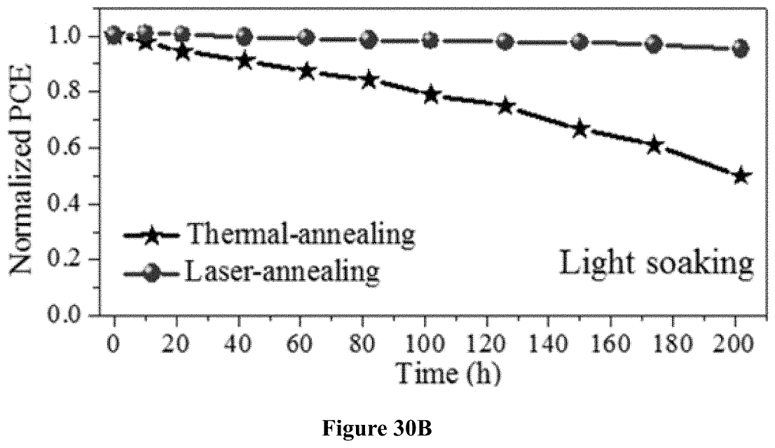

Besides, the device stability of the mixed PSCs was tested under both dark and light illumination conditions (See FIG. 30A-30B). After storing in dark for about 2000 hours, there was no obvious decrease in PCE for the device prepared by laser-annealing process, while the PCE of the control device can only retain 85% of the original value. Even under light illumination of 100 mW/cm² (AM 1.5G), the devices prepared by laser-annealing can maintain 95% of the initial PCE after light soaking test for over 200 hours, while the control devices lost about half of its value. The greatly improved device stability of the PSCs prepared by laser-annealing should be ascribed to the increased crystallinity of the perovskite films.

In accordance with certain embodiments, an ultrafast laser annealing approach is developed for the preparation of both perovskite films and mixed perovskite films at room temperature. Perovskite films can be crystalized under high-intensity laser in a few seconds and the average grain size is controlled by tuning the laser wavelength, scanning speed and laser power. Under optimum conditions, high-quality perovskite films with good crystallinity, preferred orientation and low density of defects are fabricated. The different light absorption coefficients in perovskite crystallites and amorphous phases can induce temperature gradient at the boundaries of perovskite crystallites under the laser annealing. The temperature gradient can act as a driving force for the crystallization of perovskite crystallites and lead to larger grain sizes than the conventional thermal annealing method. Furthermore, a linear laser beam is used to achieve a fast annealing process in a large area, which is highly compatible with the mass production of PSCs.

The devices based on the present laser-annealed perovskite films are more stable due to the high crystallinity of the perovskite films. Compared with the conventional technology, the present laser-annealing method consumes less time and power, while maintaining high solar cell efficiency, thus, the devices are low cost in comparison with the existing approaches. In addition, this laser-scanning method is more accurate and reliable for the controllable growth of perovskite films. Furthermore, based on the present laser-annealed perovskite films, planar device structure (e.g., FTO/SnO₂/Perovskite/spiro-OMeTAD/Au) may be used to replace the mesoporous structure, in order to simplify the device preparation process.

Although the invention has been described in terms of certain embodiments, other embodiments apparent to those of ordinary skill in the art are also within the scope of this invention. Accordingly, the scope of the invention is intended to be defined only by the claims which follow.

What is claimed is:

1. A method for preparing a laser-annealed perovskite film by one or more laser beams comprising:
providing an as-deposited perovskite film having an amorphous phase and comprising a plurality of perovskite crystallites, each perovskite crystallite being surrounded by the amorphous phase;
determining a light wavelength, at which a light absorbance ratio of the plurality of perovskite crystallites to the amorphous phase in a spectral region is larger than a threshold value, the threshold value being 80% of a largest value of the light absorbance ratio in the spectral region;
selecting a wavelength of each laser beam to be the determined light wavelength such that the plurality of perovskite crystallites absorbs more energy from the one or more laser beams and attains higher temperature than the amorphous phase thereby inducing selective growth of the plurality of perovskite crystallites for improving crystallinity of the laser-annealed perovskite film and increasing an average grain size of the laser-annealed perovskite film;
selecting a power and a scanning speed of each laser beam such that when an area of the as-deposited perovskite film is scanned by an individual laser beam with the selected wavelength, a surface temperature of the area is raised to a crystallization temperature of the as-deposited perovskite film for improving the crystallinity and increasing the average grain size; and
scanning one or more surfaces of the perovskite film by the one or more laser beams with the selected wavelength, the selected power and the selected scanning speed for annealing the as-deposited perovskite film to crystallize the as-deposited perovskite film under the selective growth of the plurality of perovskite crystallites thereby forming the laser-annealed perovskite film such that when the laser-annealed perovskite film is used in a perovskite solar cell, photovoltaic performance of the perovskite solar cell is enhanced.

2. The method of claim 1, wherein the step of determining the light wavelength comprises:
characterizing a sample of the as-deposited perovskite film with absorption spectroscopy for obtaining a first absorption spectrum;
crystallizing the sample of the as-deposited perovskite film thereby forming a crystalline perovskite film;
characterizing the crystalline perovskite film with absorption spectroscopy for obtaining a second absorption spectrum;
determining a light absorbance ratio of the crystalline perovskite film to the sample of the as-deposited perovskite film in the spectral region based on the first absorbance spectrum and the second absorbance spectrum; and
selecting the light wavelength, at which the determined light absorbance ratio of the crystalline perovskite film to the sample the as-deposited perovskite film in the spectral region is larger than the threshold value.

3. The method of claim 2, wherein the crystalline perovskite film is formed by laser-annealing or thermal annealing.

4. The method of claim 1, wherein the threshold value is 90% of the largest value.

5. The method of claim 1, wherein the spectral region is between 300 nm and 800 nm.

6. The method of claim 1, wherein each laser beam is a linear laser beam or a spot laser beam; and the selected scanning speed is controlled by a motorized stage.

7. The method of claim 1, wherein the as-deposited perovskite film is prepared by a spin-coating method.

8. The method of claim 1, wherein the as-deposited perovskite film consists of methylammonium lead iodide (MAPbI₃) or a mixed perovskite material having a chemical formula of (CsPbI₃)_{0.05}(FAPbI₃)_{0.95}(MAPbBr₃)_{0.05}.

9. A laser-annealed perovskite film prepared by the method of claim 1.

10. A perovskite solar cell comprising a laser-annealed perovskite film prepared by the method of claim 1.

11. A method for preparing a laser-annealed perovskite film by one or more laser beams comprising:
providing an as-deposited perovskite film having an amorphous phase and comprising a plurality of perovskite crystallites, each perovskite crystallite being surrounded by the amorphous phase; and
scanning one or more surfaces of the as-deposited perovskite film by the one or more laser beams with a predetermined wavelength, a predetermined power and a predetermined scanning speed for annealing the as-deposited perovskite film to crystallize the as-deposited perovskite film thereby forming the laser-annealed perovskite film;
wherein the predetermined wavelength is selected to be a light wavelength at which a light absorbance ratio of the plurality of perovskite crystallites to the amorphous phase in a spectral region is larger than a threshold value, the threshold value being 80% of a largest value of the light absorbance ratio in the spectral region such that the plurality of perovskite crystallites absorbs more energy from the one or more laser beams and attains higher temperature than the amorphous phase thereby inducing selective growth of the plurality of perovskite crystallites for improving crystallinity of the laser-annealed perovskite film and increasing an average grain size of the laser-annealed perovskite film;
wherein the predetermined power and the predetermined scanning speed are selected such that when an area of the as-deposited perovskite film is scanned by an individual laser beam with the predetermined wavelength, a surface temperature of the area is raised to a crystallization temperature of the as-deposited perovskite film for improving the crystallinity and increasing the average grain size; and
wherein the laser-annealed perovskite film is formed under the selective growth of the plurality of perovskite crystallites such that when the laser-annealed perovskite film is used in a perovskite solar cell, photovoltaic performance of the perovskite solar cell is enhanced.

12. The method of claim 11, wherein each laser beam is a linear laser beam or a spot laser beam.

13. The method of claim 12, wherein the spot laser beam has a spot size between 0.5 mm and 1.0 mm.

14. The method of claim 12, wherein the linear laser beam is generated by a cylindrical convex lens and a laser generator.

15. The method of claim 11, wherein each laser beam is generated by a laser generator.

16. The method of claim 15, wherein the laser generator is mounted on a motorized stage for controlling the predetermined scanning speed.

17. A laser-annealed perovskite film prepared by the method of claim 11.

18. A perovskite solar cell comprising a laser-annealed perovskite film prepared by the method of claim 11.

19. A method for preparing a laser-annealed perovskite film by one or more laser beams comprising:
providing an as-deposited perovskite film having an amorphous phase and comprising a plurality of perovskite crystallites, each perovskite crystallite being surrounded by the amorphous phase; and
scanning one or more surfaces of the as-deposited perovskite film by the one or more laser beams with a predetermined wavelength, a predetermined power and a predetermined scanning speed for annealing the as-deposited perovskite film to crystallize the as-deposited perovskite film thereby forming the laser-annealed perovskite film;
wherein the as-deposited perovskite film consists of MAPbI₃ or a mixed perovskite material having a chemical formula of (CsPbI₃)_{0.05}(FAPbI₃)_{0.95}(MAPbBr₃)_{0.05};
wherein the predetermined wavelength is between 445 nm and 455 nm such that the plurality of perovskite crystallites absorbs more energy from the one or more laser beams and attains higher temperature than the amorphous phase thereby inducing selective growth of the plurality of perovskite crystallites for improving crystallinity of the laser-annealed perovskite film and increasing an average grain size of the laser-annealed perovskite film;
wherein the predetermined power is between 145 mW and 155 mW and the predetermined scanning speed is between 20 mm/min and 30 mm/min such that when an area of the perovskite film is scanned by an individual laser beam with the predetermined wavelength, a surface temperature of the area is raised to a crystallization temperature of the as-deposited perovskite film for improving the crystallinity and increasing the average grain size; and
wherein the laser-annealed perovskite film is formed under the selective growth of the plurality of perovskite crystallites such that when the laser-annealed perovskite film is used in a perovskite solar cell, photovoltaic performance of the perovskite solar cell is enhanced.

20. A laser-annealed perovskite film prepared by the method of claim 19.
